(19) United States
(12) Patent Application Publication
(10) Pub. No.: US 2025/0313749 A1
(43) Pub. Date: Oct. 9, 2025

(54) METAL COMPLEX AND ORGANIC LIGHT-EMITTING ELEMENT

(71) Applicant: CANON KABUSHIKI KAISHA, Tokyo (JP)

(72) Inventor: AKIRA TSUBOYAMA, Tokyo (JP)

(21) Appl. No.: 19/246,270

(22) Filed: Jun. 23, 2025

Related U.S. Application Data
(63) Continuation of application No. PCT/JP2023/044215, filed on Dec. 11, 2023.

(30) Foreign Application Priority Data
Dec. 26, 2022 (JP) 2022-208031
Sep. 19, 2023 (JP) 2023-151186

(51) Int. Cl. C09K 11/06; C07F 15/00; H10K 50/12; H10K 59/121; H10K 85/30

(52) U.S. Cl. CPC C09K 11/06; H10K 50/12; H10K 59/1213; H10K 85/342; C07F 15/0033; C07F 15/0073; C09K 2211/185

(57) ABSTRACT

A metal complex containing Ir or Rh contains 1,4-di(pyridin-2-yl)benzene as the main ligand.

### CROSS-REFERENCE TO RELATED APPLICATIONS

This application is a Continuation of International Patent Application No. PCT/JP2023/044215, filed Dec. 11, 2023, which claims the benefit of Japanese Patent Application No. 2022-208031, filed Dec. 26, 2022 and No. 2023-151186, filed Sep. 19, 2023, all of which are hereby incorporated by reference herein in their entirety.

### BACKGROUND

### Field of the Technology

The present disclosure relates to a metal complex, an organic light-emitting element containing the metal complex, and devices and apparatuses that include the organic light-emitting element.

### Description of the Related Art

An organic light-emitting element is an electronic element including a first electrode, a second electrode, and an organic compound layer disposed between these electrodes. Electrons and holes are injected into the organic compound layer from the pair of electrodes, thereby generating excitons in the luminescent material in the organic compound layer. When the excitons return to the ground state, the organic light-emitting element emits light. Organic light-emitting elements are also called organic electroluminescent elements or organic EL elements.

Luminescent materials are roughly classified into two types based on their

luminescence principle: fluorescent materials and phosphorescent materials. In organic light-emitting elements, phosphorescent materials, which emit light from the triplet excited state, are known to have a higher luminescence quantum yield than fluorescent materials, which emit light from the singlet excited state. For example, NPL 1 describes Ir(ppy)₃, a metal complex having the following structure, as a green phosphorescent material. Also, NPL 2 describes the emission spectrum of the following metal complex A:

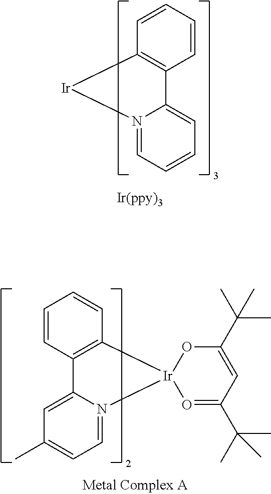

Organic light-emitting elements containing 4,4′-di(N-carbazolyl)biphenyl (CBP) doped with Ir(ppy)₃ emit green light with an emission wavelength of 510 nm, and it is reported that the external quantum efficiency of such organic light-emitting elements is 13% and is much higher than the quantum efficiency limit (5%) of conventional singlet emitting elements.

PTL 1 discloses an Ir complex in which the phenyl group of the 2-phenylpyridine ligand in Ir(ppy)₃ is substituted with pyridine or triazine bearing an alkyl group as a substituent. Also, PTL 2 discloses an Ir complex with a molecular structure having a quinoline or isoquinoline ring in the ligand directly bound to Ir and further having a quinoline or isoquinoline ring as a substituent.

### CITATION LIST

### Patent Literature

PTL 1 Japanese Patent Laid-Open No. 2021-59528

PTL 2 U.S. Pat. No. 8,481,173

NPL 1 Appl. Phys. Lett. Vol. 75, No. 4, 1999

NPL 2 Adv. Optical Mater. 2015, 3, 1191-1196

Ir(ppy)₃ exhibits a broad emission spectrum with a half width (FWHM) of 59 nm. Therefore, organic light-emitting elements using Ir(ppy)₃ as a light-emitting dopant exhibit broad emission spectra, which lead disadvantageously to a narrow color reproduction range. The same disadvantage applies to any emission colors, and the emission spectrum of luminescent materials is desirably narrow. Colors such as RGBY may be used in applications other than display devices. In general, narrower emission spectra are desirable because the emission color gamut is expanded by narrowing the emission spectrum.

The emission spectrum of the Ir complex disclosed in PTL 1 is narrowed by introducing pyrimidine or triazine bearing an alkyl group to the ligand of Ir(ppy)₃. Unfortunately, such a substituent is generally highly electron-accepting. Accordingly, this Ir complex easily traps electrons and, therefore, may limit the selection of peripheral materials such as host materials when used as a light-emitting dopant in organic light-emitting elements.

PTL 2 does not describe the shape and half width of the emission spectrum.

### SUMMARY

The present disclosure provides a highly efficient, stable luminescent material that can achieve high color purity.

The metal complex of the present disclosure is represented by the following general formula (1):

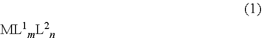

In the above general formula (1), M represents Ir or Rh, and L¹ and L² represent ligands different from each other.

m represents an integer of 2 or 3, n represents an integer of 0 or 1, and m+n=3 holds true.

ML¹ is represented by the following general formula (2), and ML² is represented by any of the following general formulas (3) to (5):

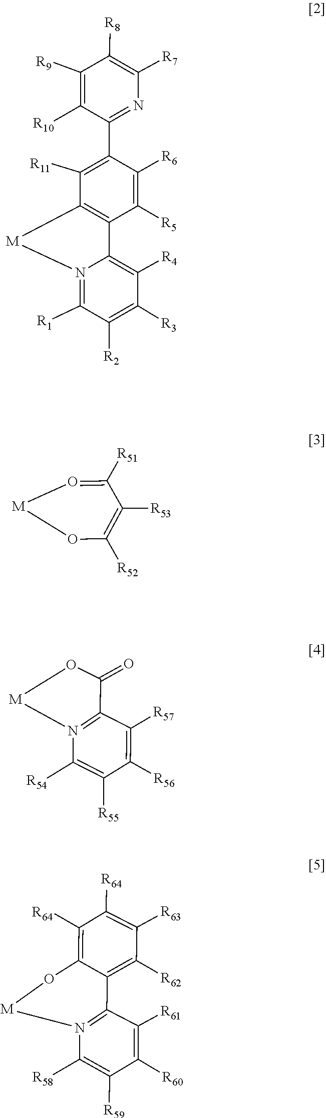

In the above general formula (2), R₁ to R₁₁ are each independently selected from the group consisting of a hydrogen atom, a fluorine atom, a substituted or unsubstituted aryl group, a linear, branched, or cyclic alkyl group, and a triphenylsilyl group, and the hydrogen atoms of the alkyl and triphenylsilyl groups are optionally substituted with an alkyl group or a fluorine atom.

In the above general formulas (3) to (5), R₅₁ to R₆₅ are each independently selected from the group consisting of a hydrogen atom, a deuterium atom, a halogen atom, a substituted or unsubstituted alkyl group, a substituted or unsubstituted alkoxy group, a substituted or unsubstituted aralkyl group, a substituted or unsubstituted amino group, a substituted or unsubstituted aryl group, and a substituted or unsubstituted heterocyclic group.

Features of the present disclosure will become apparent from the following description of exemplary disclosures with reference to the attached drawings.

### BRIEF DESCRIPTION OF THE DRAWINGS

FIG. 1A is a schematic sectional view of an example of a pixel in a display device according to the present disclosure.

FIG. 1B is a schematic sectional view of an example of a display device using an organic light-emitting element according to the present disclosure.

FIG. 2 is a schematic illustrative representation of an example of a display device using an organic light-emitting element according to the present disclosure.

FIG. 3A is a schematic illustrative representation of an example of an imaging device according to the present disclosure.

FIG. 3B is a schematic illustrative representation of an example of a mobile device according to the present disclosure.

FIG. 4A is a schematic illustrative representation of an example of a display device according to the present disclosure.

FIG. 4B is a schematic illustrative representation of an example of foldable display devices.

FIG. 5A is a schematic illustrative representation of an example of a lighting device according to the present disclosure.

FIG. 5B is a schematic illustrative representation of an automobile that is an example of the movable apparatus according to the present disclosure.

FIG. 6A is a schematic illustrative representation of an example of a wearable device according to the present disclosure.

FIG. 6B is a schematic illustrative representation of an example of a wearable device according to the present disclosure, including an imaging device.

FIG. 7 is a molecular structure image of Example Compound 1 of the metal complex according to the present disclosure, analyzed by X-ray crystallographic analysis.

FIG. 8 is a representation of the PL emission spectra of Example Compounds 1 and 2 of the metal complex according to the present disclosure and Comparative Compound 1.

### DESCRIPTION OF THE DISCLOSURES

Some disclosures of the present disclosure will now be described. The present disclosure is not limited by the following description, and it will be easily understood by those skilled in the art that various modifications in form and detail may be made provided that the form and details do not depart from the spirit and scope of the disclosure. Hence, the present disclosure is not to be interpreted as limited by the following description.

As described above, when a metal complex exhibiting an emission spectrum with a broad half width (FWHM) is used as a light-emitting dopant in an organic light-emitting element, the element does not emit light with high color purity. To achieve a light-emitting device with high color purity, complex optical design is required for high color purity. However, if the emission spectrum of a light-emitting dopant is narrow from the beginning, a light-emitting devices with high color purity can be achieved without placing a large burden on the device design. It has been an issue in developing light-emitting dopants to reduce the half width of the light-emitting dopant to increase color purity.

As a result of eager research for this issue, the present inventor has identified a metal complex that exhibits an emission spectrum with a narrow half width.

### Metal Complex Represented by General Formula (1)

The metal complex disclosed herein is represented by the following general formula (1):

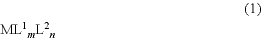

In the above general formula (1), M represents Ir or Rh, and L¹ and L² represent ligands different from each other.

m represents an integer of 2 or 3, n represents an integer of 0 or 1, and m+n=3 holds true.

ML¹ is represented by the following general formula (2), and ML² is represented by any of the following general formulas (3) to (5).

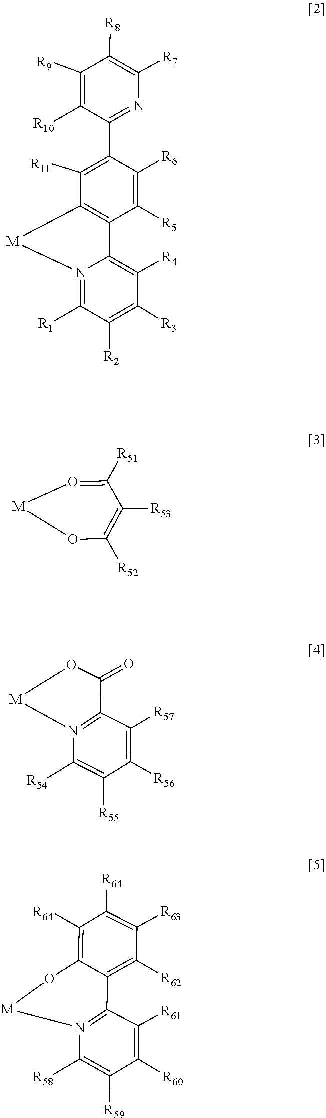

In the above general formula (2), R₁ to R₁₁ are each independently selected from the group consisting of a hydrogen atom, a fluorine atom, a substituted or unsubstituted aryl group, a linear, branched, or cyclic alkyl group, and a triphenylsilyl group, and the hydrogen atoms of the alkyl and triphenylsilyl groups are optionally substituted with an alkyl group or a fluorine atom.

In the above general formulas (3) to (5), R₅₁ to R₆₅ are each independently selected from the group consisting of a hydrogen atom, a deuterium atom, a halogen atom, a substituted or unsubstituted alkyl group, a substituted or unsubstituted alkoxy group, a substituted or unsubstituted aralkyl group, a substituted or unsubstituted amino group, a substituted or unsubstituted aryl group, and a substituted or unsubstituted heterocyclic group.

The metal complex disclosed herein contains Ir or Rh as the central metal and 1,4-di(pyridin-2-yl)benzene as the main skeleton of a ligand. The central metal, that is, M in general formula (1), is preferably Ir.

The metal complex disclosed herein preferably satisfy m=3 and n=0 in general formula (1).

The alkyl and aryl groups mentioned as R₁ to R₁₁ and the alkyl, alkoxy, aralkyl, amino, aryl, and heterocyclic groups mentioned as R₅₁ to R₆₅ will be described in detail below.

Halogen atoms include, but are not limited to, fluorine, chlorine, bromine, and iodine. In some embodiments, fluorine is preferred among the halogen atoms.

The alkyl group preferably has 1 to 10 carbon atoms, more preferably 1 to 8 carbon atoms, and still more preferably 1 or 4 carbon atoms. Specifically, examples of the alkyl group include, but are not limited to, a methyl group, an ethyl group, a n-propyl group, an isopropyl group, a n-butyl group, a tert-butyl group, a sec-butyl group, an ethylhexyl group, an octyl group, a cyclopentyl group, a cyclohexyl group, a 1-adamantyl group, and a 2-adamantyl group.

The alkoxy group preferably has 1 to 10 carbon atoms, more preferably 1 to 6 carbon atoms, and still more preferably 1 or 4 carbon atoms. Specifically, examples of the alkoxy group include, but are not limited to, a methoxy group, an ethoxy group, a propoxy group, a 2-ethylhexyloxy group, and a benzyloxy group.

The aralkyl group is an alkyl group substituted with an aryl group, and the alkyl group preferably has 1 to 10 carbon atoms, more preferably 1 to 8 carbon atoms, and still more preferably 1 or 4 carbon atoms. Specifically, examples of the alkyl group include, but are not limited to, a methyl group, an ethyl group, a n-propyl group, an isopropyl group, a n-butyl group, a tert-butyl group, a sec-butyl group, an octyl group, a cyclopentyl group, a cyclohexyl group, a 1-adamantyl group, and a 2-adamantyl group. The aryl group to be introduced as a substitute to the alkyl group may have 6 to 18 carbon atoms, and examples include, but are not limited to, a phenyl group, a naphthyl group, an indenyl group, a biphenyl group, a terphenyl group, a fluorenyl group, a phenanthryl group, and a triphenylenyl group.

The amino group may be unsubstituted or substituted with any of an alkyl group, an aryl group, or an amino group. The alkyl, aryl, and amino groups as the substituent may be substituted with a halogen atom, and the aryl and amino groups may be substituted with an alkyl group. The amino group may have a ring formed by binding alkyl substituents to each other. Specifically, examples of the amino group include, but are not limited to, an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-tert-butylphenyl)amino group, an N-phenyl-N-(4-trifluoromethylphenyl)amino group, and an N-piperidyl group.

The aryl group preferably has 6 to 18 carbon atoms, and examples include, but are not limited to, a phenyl group, a naphthyl group, an indenyl group, a biphenyl group, a terphenyl group, a fluorenyl group, a phenanthryl group, and a triphenylenyl group.

The heterocyclic group preferably has 3 to 15 carbon atoms and may contain N, S, or O as the heteroatom. Specifically, examples of the heterocyclic group include, but are not limited to, a pyridyl group, a pyrazyl group, a pyrimidyl group, a triazyl group, an imidazolyl group, an oxazolyl group, an oxadiazolyl group, a thiazolyl group, a thiadiazolyl group, a carbazolyl group, an acridinyl group, a phenanthrolyl group, a furanyl group, a thiophenyl group, a dibenzofuranyl group, and a dibenzothiophenyl group.

Substituents that the aryl group mentioned as R₁ to R₁₁ and that the alkyl, alkoxy, aralkyl, amino, aryl, and heterocyclic groups mentioned as R₅₁ to R₆₅ may further have include a halogen atom, an alkyl group, an aryl group, a heterocyclic group, an amino group, an aralkyl group, an alkoxy group, an aryloxy group, and a cyano group.

The halogen atom as the substituent may be fluorine, chlorine, bromine, or iodine, and is preferably a fluorine atom. In particular, fluorine atoms are preferably substituted for hydrogen atoms of an alkyl group to form a trifluoromethyl group (—CF₃) or a pentafluoroethyl group (—C₂F₅).

The alkyl group as the substituent preferably has 1 to 10 carbon atoms. Specifically, examples of such alkyl groups include a methyl group, an ethyl group, an n-propyl group, an isopropyl group, a n-butyl group, and a tert-butyl group.

The aryl group as the substituent preferably has 6 to 12 carbon atoms, and specific examples include a phenyl group, a biphenyl group, and a naphthyl group. The heterocyclic group preferably has 3 to 9 carbon atoms, and its heteroatom is preferably nitrogen, sulfur, or oxygen. Specifically, the heterocyclic group may be a pyridyl group or a pyrrolyl group. The amino group may be substituted with alkyl or aryl groups, and the alkyl group may bind to each other to form a ring. Specifically, examples of the amino group include a dimethylamino group, a diethylamino group, a dibenzylamino group, a diphenylamino group, and a ditolylamino group. The aralkyl group may be a benzyl group. The alkoxy group may be a methoxy group, an ethoxy group, or a propoxy group. The aryloxy group may be a phenoxy group.

The alkyl group and fluorine atom that may substitute for the hydrogen of the alkyl and triphenylsilyl groups mentioned as R₁ to R₁₁ may be the same as the alkyl group and fluorine atom mentioned as R₁ to R₁₁.

The metal complex disclosed herein will now be described.

It is known that the emission spectra of metal complexes can be narrowed by

suppressing structural changes in the excited state. In the present disclosure, it is important to suppress the internal rotation of substituents in order to suppress structural changes in the excited state. The internal rotation is suppressed by hydrogen bonds in the ligands, and similarly, the structural changes are small in the excited state. Thus, the half width in the emission spectrum can be reduced.

Now, Table 1 below presents the emission characteristics of later-described example compounds of the metal complex disclosed herein and comparative compounds that do not correspond to the metal complex disclosed herein. The emission peaks and their half widths are identified from spectra measured with a spectrophotometer F4500 manufactured by Hitachi.

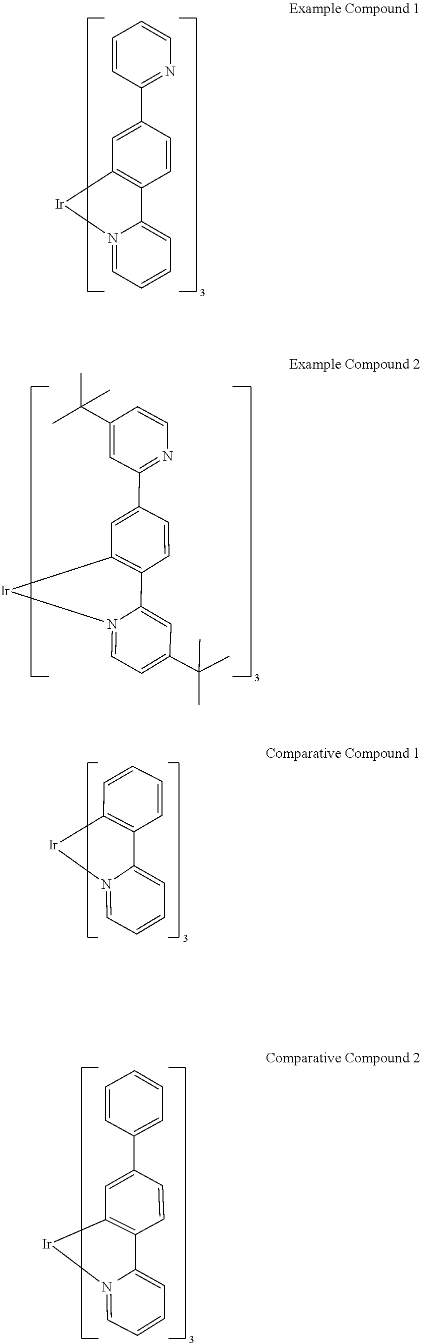

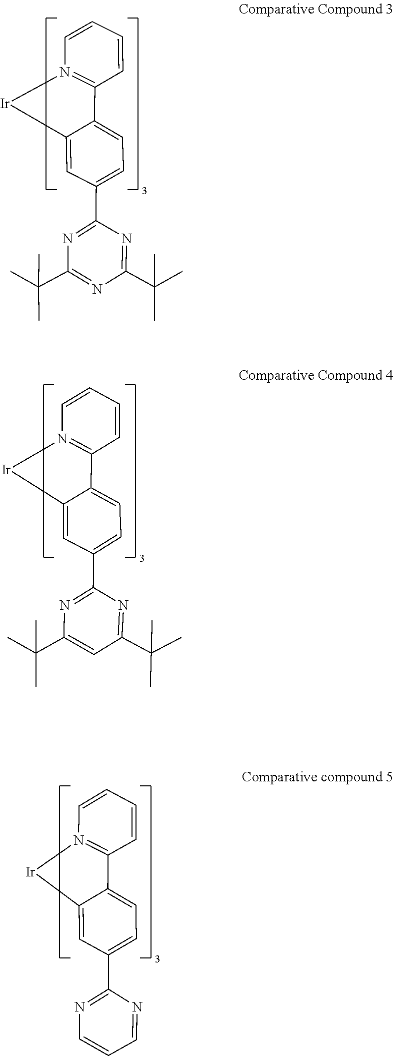

TABLE 1

| | Emission peak (nm) | Half width (nm) |
|---|---|---|
| Example Compound 1 | 541 | 31 |
| Example Compound 2 | 538 | 26 |
| Comparative Compound 1 | 509 | 59 |
| Comparative Compound 2 | 531 | 63 |
| Comparative Compound 3 | 549 | 33 |
| Comparative Compound 4 | 562 | 37 |
| Comparative Compound 5 | 545 | 70 |

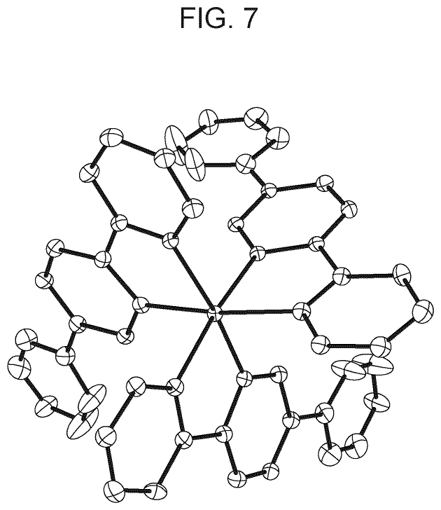

The relationship between the molecular structure and the emission characteristics will first be described. FIG. 7 depicts the molecular structure image of Example Compound 1 obtained by X-ray crystallographic analysis. The feature is that the ligands, 1,4-di(pyridin-2-yl)benzene, have a substantially planar structure. It is generally considered that each pyridyl group and the phenyl group have a certain internal rotation angle therebetween due to the repulsion of their closest hydrogen atoms. The research by the present inventor revealed that the ligands in the metal complex disclosed herein maintain their planar structure by the hydrogen bonds between the N atoms of the respective pyridyl groups and the adjacent hydrogen atoms of the phenyl group.

Comparative Compounds 3 and 4, which are the metal complexes disclosed in PTL 1, incorporate a pyrimidyl or triazinyl group to suppress the internal rotation in the ligand. These are considered to be designed to maintain the planar structure by eliminating hydrogen atoms that cause repulsion between the substituent and the phenyl group. In contrast, the metal complex disclosed herein uses a molecular moiety having the same structure as the pyridyl group used to bind to the metal. This is an advantage, for example, in simplifying the synthesis process.

Also, the half widths of the emission spectra of Comparative Compounds 3 and 5 are 33 nm and 70 nm, respectively. The difference between them is due to the presence or absence of tert-butyl groups in the molecular structure. Comparative Compound 5, in which the pyrimidyl group is not substituted with the tert-butyl group, is highly electron-accepting. It is, therefore, thought that electrons are likely to be unevenly distributed to the pyrimidyl group in the ground state and migrate to the other portions of the ligand in the excited state. It is generally known that electron migration in the excited state broadens the emission spectrum. The above-mentioned electron migration within the ligand probably contributes to the increase of the half width of the emission spectrum. In the case of Comparative Compound 3, in which the pyrimidyl group is substituted with tert-butyl groups, the electron-donating characteristics of the tert-butyl groups reduce the electron-accepting characteristics of the pyrimidyl group and thus suppress the above-mentioned electron migration in the excited state. This is probably the reason for the narrow half width.

The ligand of the metal complex disclosed herein is the pyridyl group, which is relatively less electron-accepting. Thus, the electron migration within the ligand does not contribute to the increase of the half width. It is, therefore, not necessary to add an alkyl group to a specific position of the heterocyclic aromatic substituent, as disclosed in PTL 1.

However, the addition of a substituent such as an alkyl group to a desired position of the ligand may improve properties, for example, (1) increasing the solubility to facilitate the purification process after the reaction; and (2) reducing the deposition temperature when vapor deposition is performed. The addition of a substituent such as an alkyl group is also useful in the present disclosure.

In the present disclosure, a specific structure is given to the ligands to reduce the distortion in the excited state, thereby providing a highly efficient, stable metal complex luminescent material with a narrow half width.

Specific examples of preferred ligands of the metal complex disclosed herein, that is, L¹ and L² in general formula (1), will be presented below. L1 to L11 are examples of L¹, and L21 to L28 are preferred examples of L².

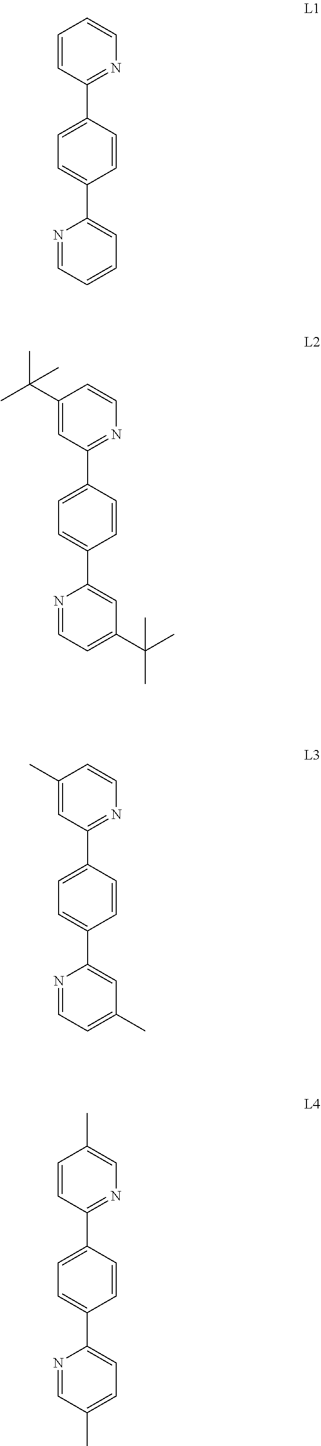

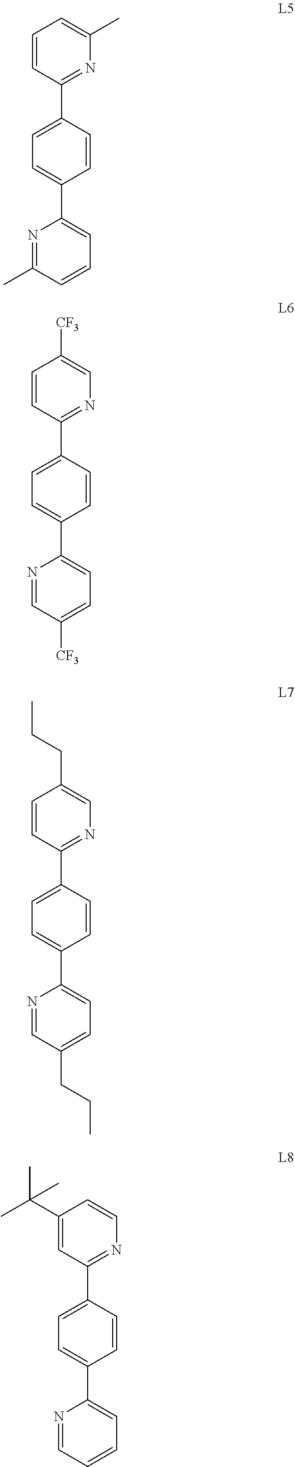

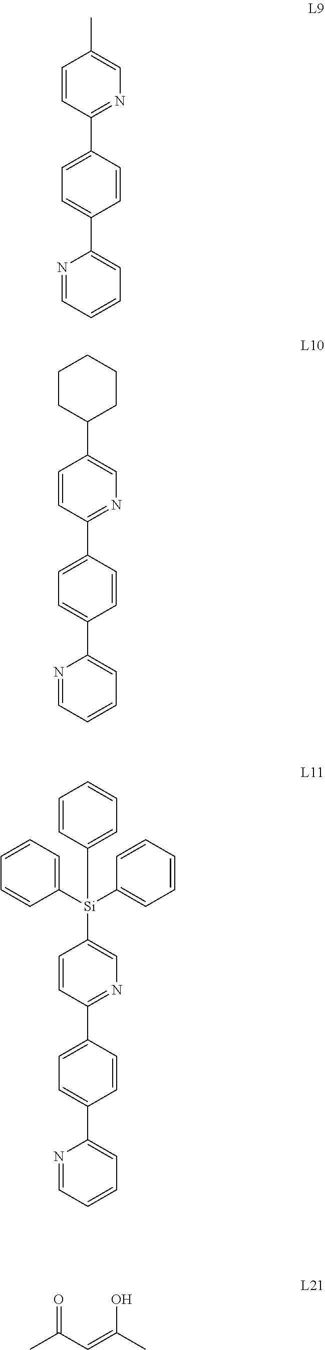

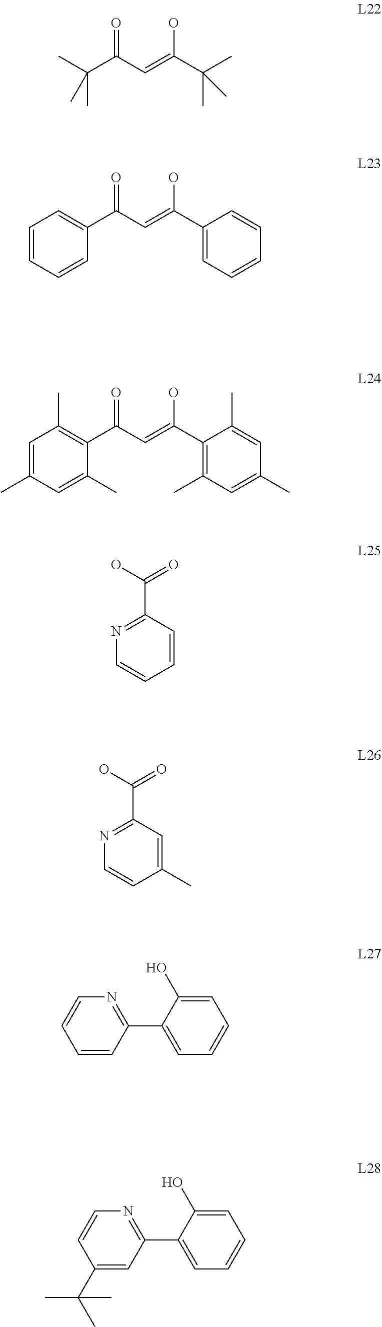

Specific preferred examples of the metal complex disclosed herein will be presented below.

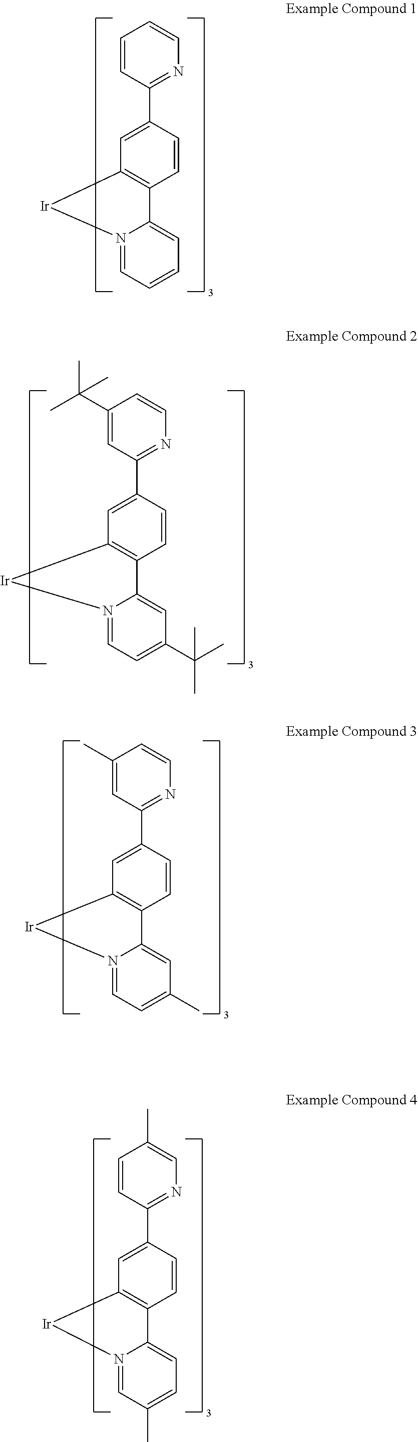

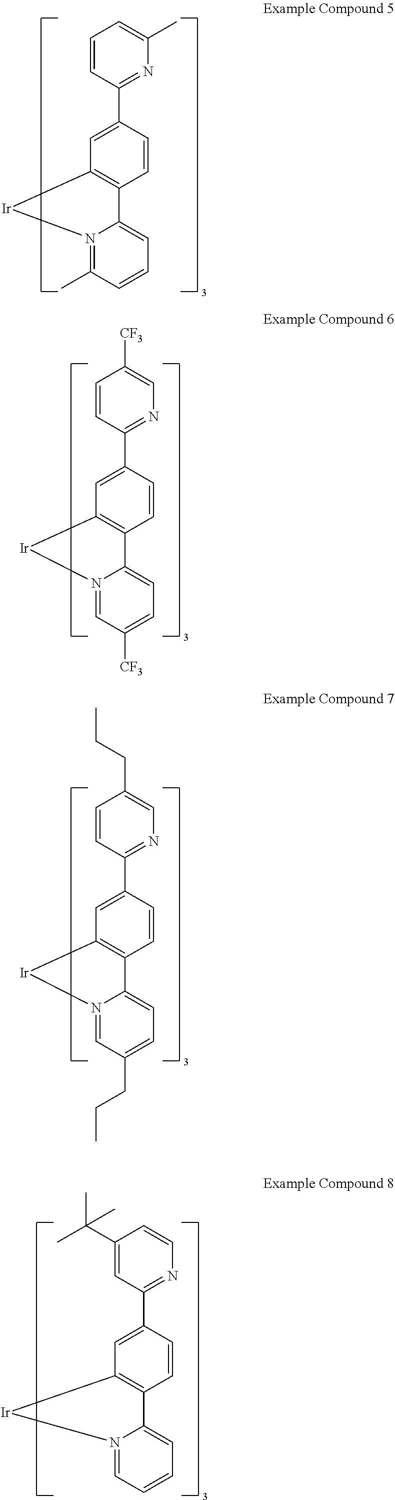

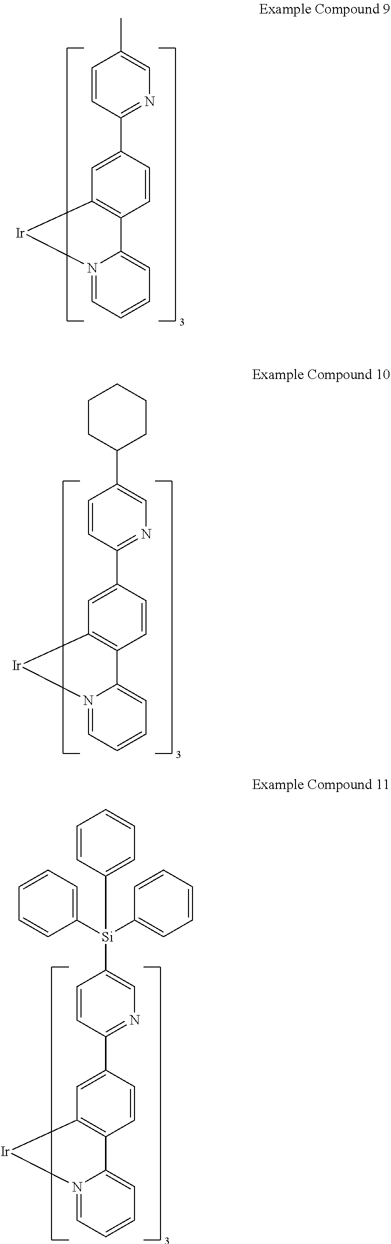

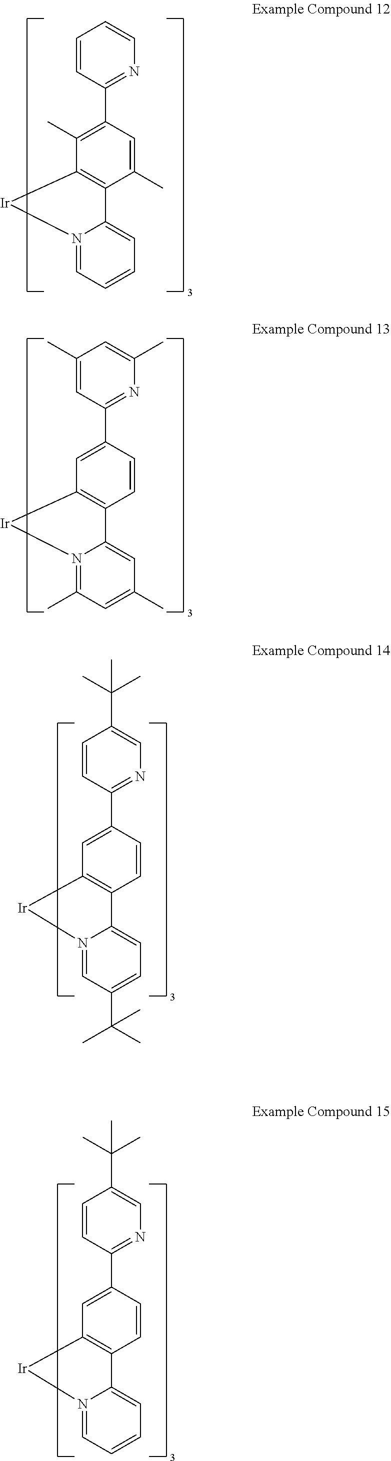

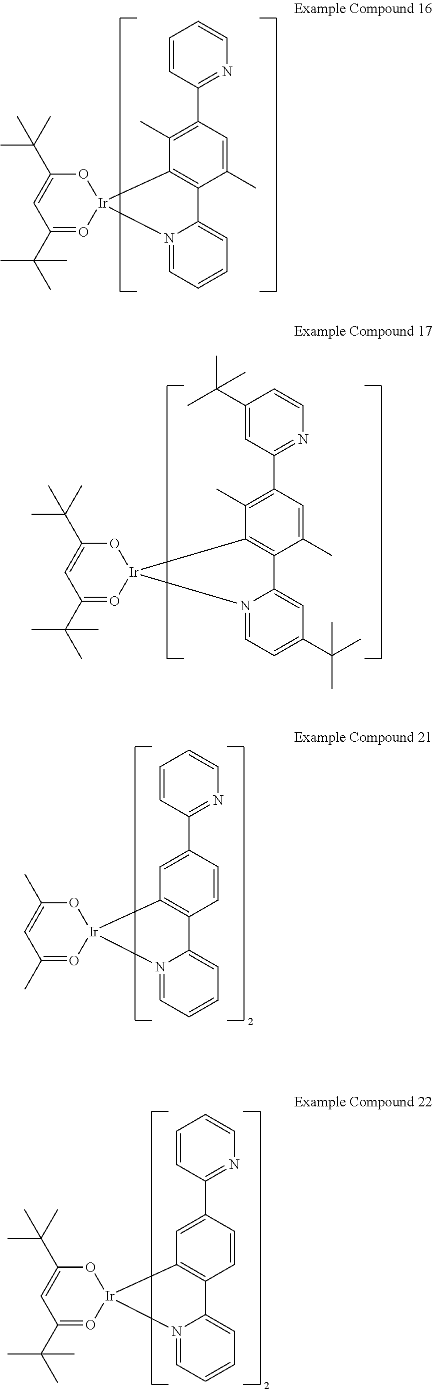

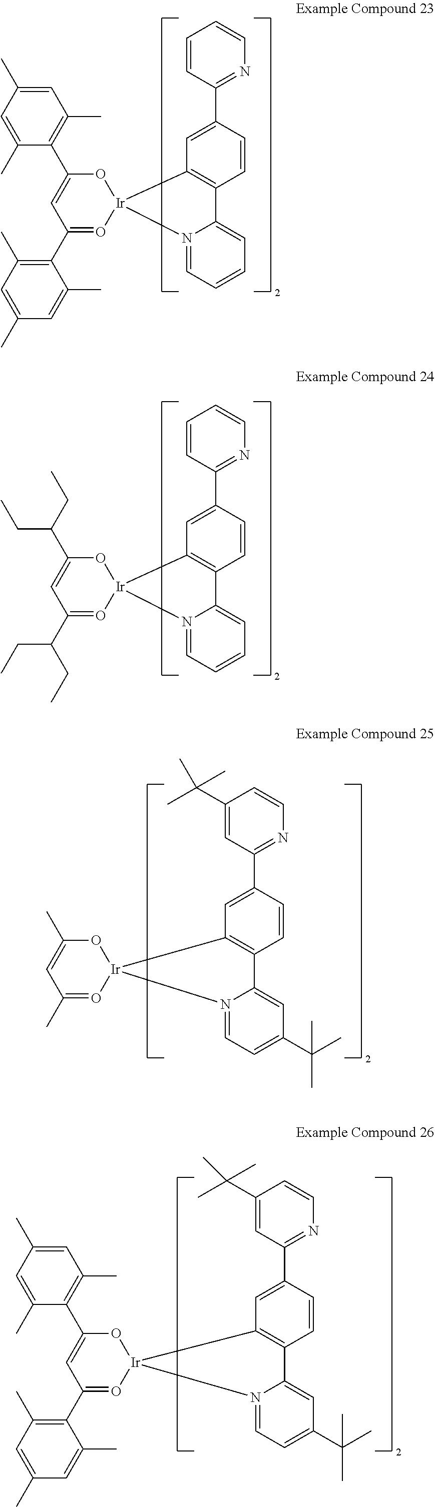

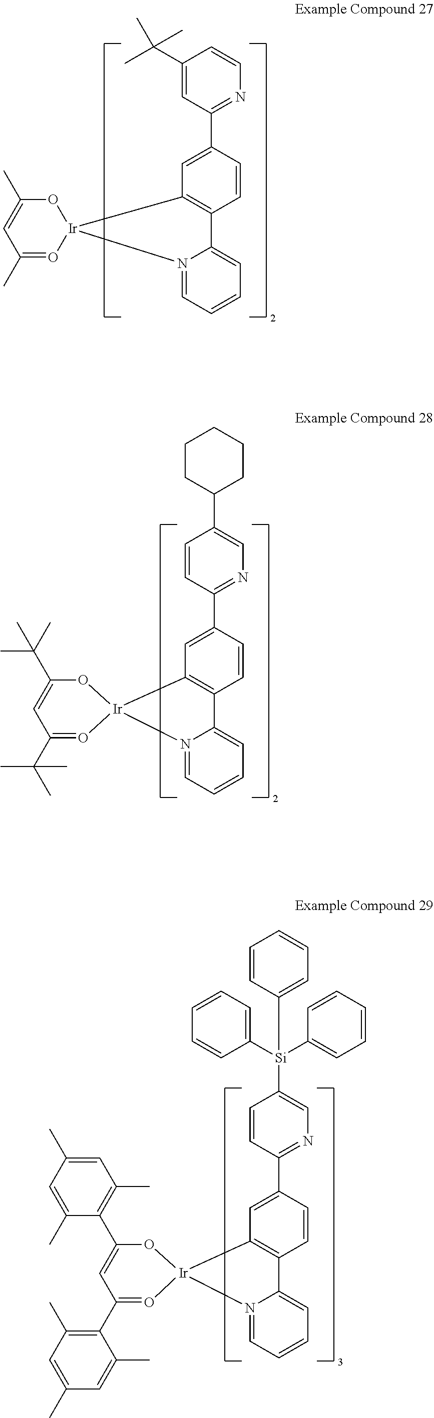

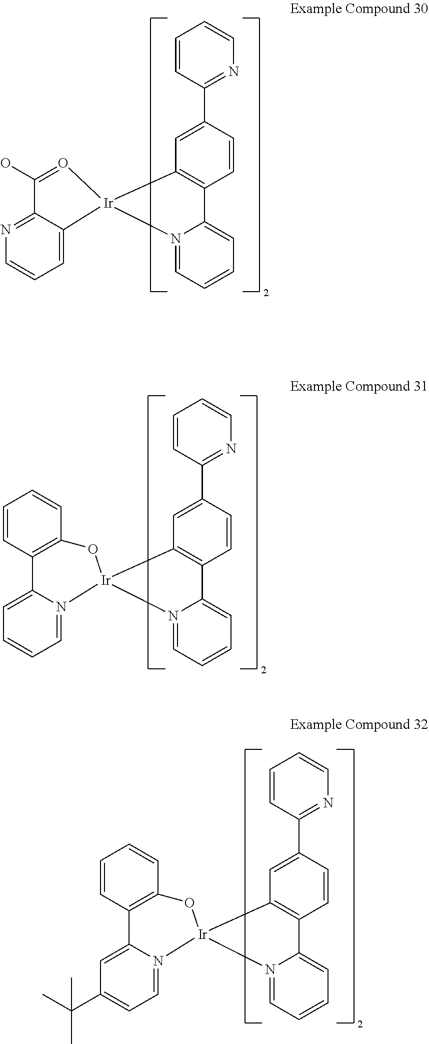

### Organic Light-Emitting Element

The metal complex disclosed herein is suitably used in a component of an organic light-emitting element. The organic light-emitting element includes a first electrode, a second electrode, and an organic compound layer between the first and second electrodes, and the organic compound layer includes at least a light-emitting layer.

The structure of the organic light-emitting element will now be described.

### Organic Compound Layer

The organic compound layer may be composed of a single layer or have a multilayer structure including a plurality of layers, provided that the organic compound layer includes a light-emitting layer. When the organic compound layer has a multilayer structure including a plurality of layers, the organic compound layer may include, a hole injection layer, a hole transport layer, an electron blocking layer, a hole/exciton blocking layer, an electron transport layer, and an electron injection layer, in addition to the light-emitting layer. The light-emitting layer may be composed of a single layer or have a multilayer structure including a plurality of layers. The hole transport layer and the electron transport layer are also referred to as charge transport layers.

In the organic light-emitting element disclosed herein, at least one of the above-mentioned organic compound layers contains the metal complex disclosed herein. Specifically, the metal complex disclosed herein is contained in any of the above-mentioned hole injection layer, hole transport layer, electron blocking layer, light-emitting layer, hole/exciton blocking layer, electron transport layer, electron injection layer, or the like, and preferably in the light-emitting layer. The layers between the first electrode and the light-emitting layer may be collectively referred to as the first charge transport layer. The layers between the second electrode and the light-emitting layer may be collectively referred to as the second charge transport layer. In other words, the light-emitting layer is in contact with the first charge transport layer and the second charge transport layer.

In the disclosures of the organic light-emitting element in which the light-emitting layer contains the metal complex disclosed herein, the light-emitting layer may be made of only the metal complex or may contain a first organic compound and a second organic compound different from the first organic compound in addition to the metal complex. The lowest excited triplet energy of the first organic compound may be lower than the lowest excited triplet energy of the iridium complex of the present disclosure. The lowest excited triplet energy of the second organic compound may be equal to or higher than the lowest excited triplet energy of the metal complex disclosed herein and lower than or equal to the lowest excited triplet energy of the first organic compound. When the light-emitting layer contains the first organic compound and the second organic compound, the first organic compound may be the host of the light-emitting layer. The second compound layer may be an assist material. The metal complex disclosed herein may be a guest or dopant, preferably a light-emitting dopant.

The host used here refers to the compound accounting for the highest percentage of the total mass of the compounds in the light-emitting layer. Also, the guest or dopant refers to a compound in a lower percentage by mass than the host in the light-emitting layer and is responsible for the main luminescence. The assist material refers to a compound in a lower percentage by mass than the host in the light-emitting layer and helps the guest emit light. The assist material is also called the second host.

When the metal complex disclosed herein is used as a light-emitting dopant, the concentration of the metal complex is preferably 0.01% to 20% by mass, more preferably 0.1% to 10.0% by mass, relative to the entirety of the light-emitting layer. The entirety of the light-emitting layer refers to the total mass of the compounds in the light-emitting layer.

Also, the lowest excited triplet energy of the first charge transport layer is preferably higher than the lowest excited triplet energy of the first organic compound. Also, the lowest excited triplet energy of the second charge transport layer is preferably higher than the lowest excited triplet energy of the first organic compound. The lowest excited triplet energy of the charge transport layers can be estimated from the lowest excited triplet energies of the constituents of the layer. When a charge transport layer contains a plurality of materials, its lowest excited triplet energy can be that of the compound accounting for the largest proportion of the layer.

The present inventor has found through his various studies that the metal complex disclosed herein outputs highly efficient and highly bright emission and exhibits improved roll-off behavior when used as a light-emitting dopant. The light-emitting layer may be composed of a single layer or may have a multilayer structure. Also, the light-emitting layer may contain another luminescent material having another emission color to emit a color mixed with the emission color according to the present disclosure. The multilayer structure refers to a state where a plurality of light-emitting layers are stacked one on top of another. In this instance, the emission color of the organic light-emitting element is not limited to the same hue as the emission color of the single-layer light-emitting layer. More specifically, the emission color may be white or an intermediate color. White emission may be produced by light-emitting layers respectively emitting red, blue, and green light or by combining complementary emission colors.

The metal complex disclosed herein may also be used as a constituent of the organic compound layers of the organic light-emitting element disclosed herein, other than the light-emitting layer. Specifically, the metal complex may be used as a constituent of the electron transport layer, the electron injection layer, the hole transport layer, the hole injection layer, the hole blocking layer, or the like.

When the organic light-emitting element disclosed herein is manufactured, known low-molecular-weight or polymeric compounds that can be a hole injecting or hole transporting compound, a host, a luminescent material, an electron injecting or electron transporting compound, and the like may optionally be used together. Examples of these compounds are presented below.

The hole injecting or transporting material preferably has a high hole mobility so as to facilitate the injection of holes from the anode and transport the injected holes to the light-emitting layer. Also, the hole injecting or transporting material preferably has a high glass transition temperature so as to reduce the crystallization or other deterioration of the layer in the organic light-emitting element. Low-molecular-weight or polymeric hole injecting or transporting materials include triarylamine derivatives, aryl carbazole derivatives, phenylenediamine derivatives, triazole derivatives, oxadiazole derivatives, imidazole derivatives, stilbene derivatives, phthalocyanine derivatives, porphyrin derivatives, polyarylamine derivatives, polyvinylcarbazole derivatives, polythiophene derivatives, and other electrically conductive polymers such as PEDOT-PSS, and their copolymers or mixtures. Such a hole injecting or transporting material is also suitably used in the electron blocking layer.

Examples of the compounds that can be used as the hole injecting or transporting material include, but are not limited to, the following.

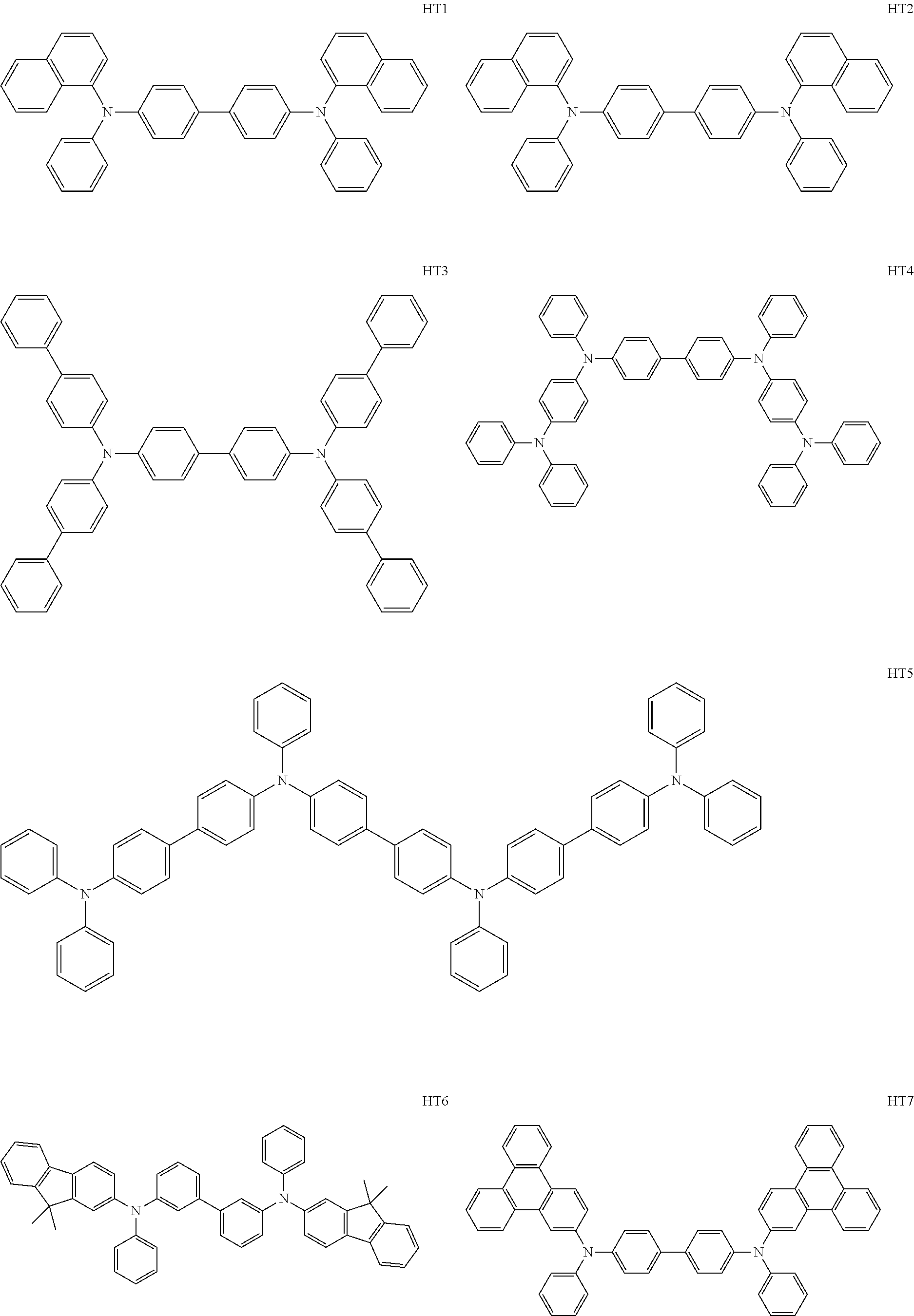

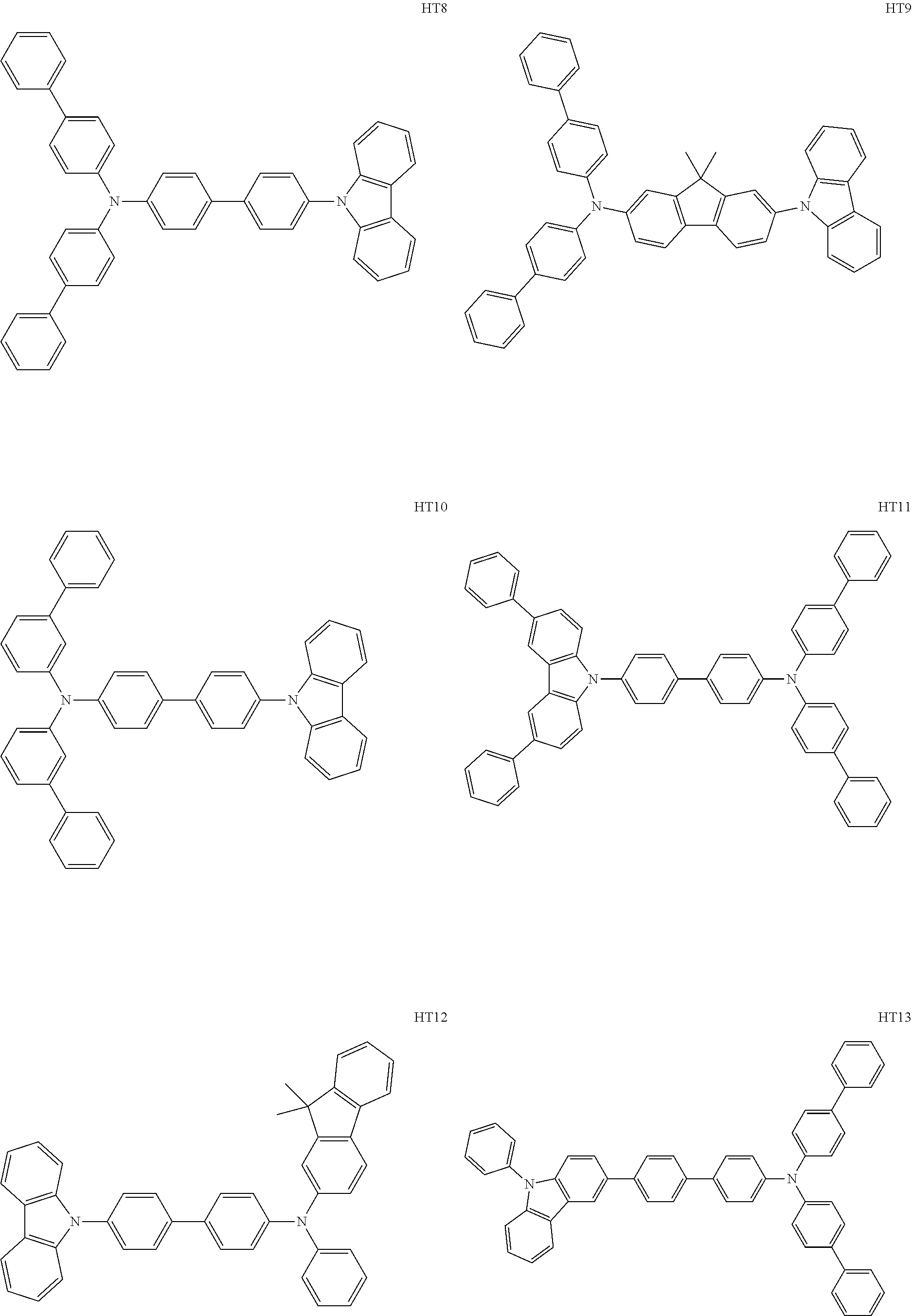

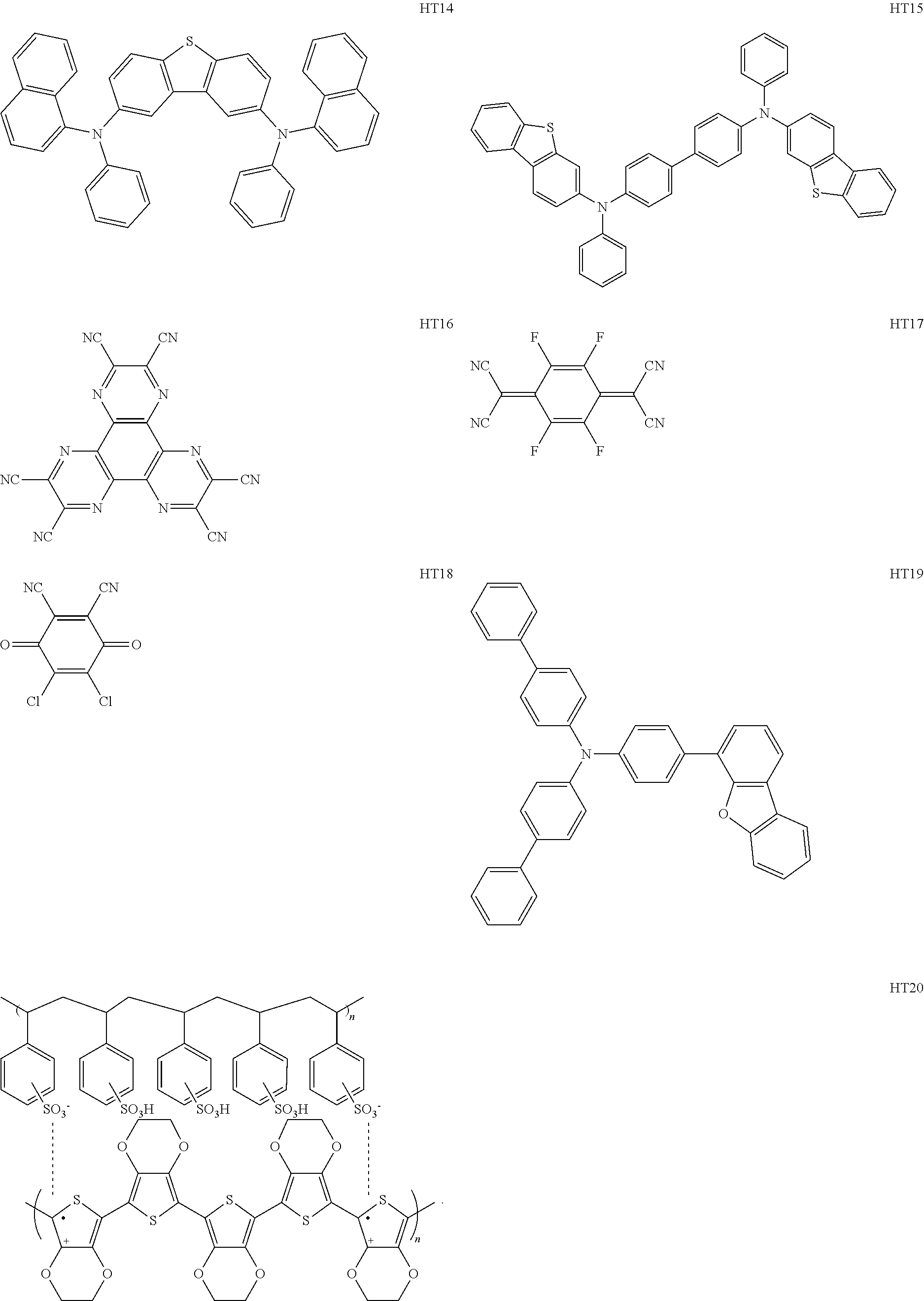

In addition to the metal complex disclosed herein, other luminescent materials may be added as luminescent materials mainly involved in light emission. Such other luminescent materials include fused ring compounds (such as fluorene derivatives, naphthalene derivatives, pyrene derivatives, perylene derivatives, tetracene derivatives, anthracene derivatives, and rubrene), quinacridone derivatives, coumarin derivatives, stilbene derivatives, organoaluminum complexes such as tris(8-quinolinolato)aluminum, iridium complexes such as tris(2-phenylpyridinato)iridium, platinum complexes, rhenium complexes, copper complexes, europium complexes, ruthenium complexes, and polymer derivatives such as poly(phenylene vinylene) derivatives, poly(fluorene) derivatives, and poly(phenylene) derivatives.

Specific examples of compounds that can be used as the luminescent material include, but are not limited to, the following:

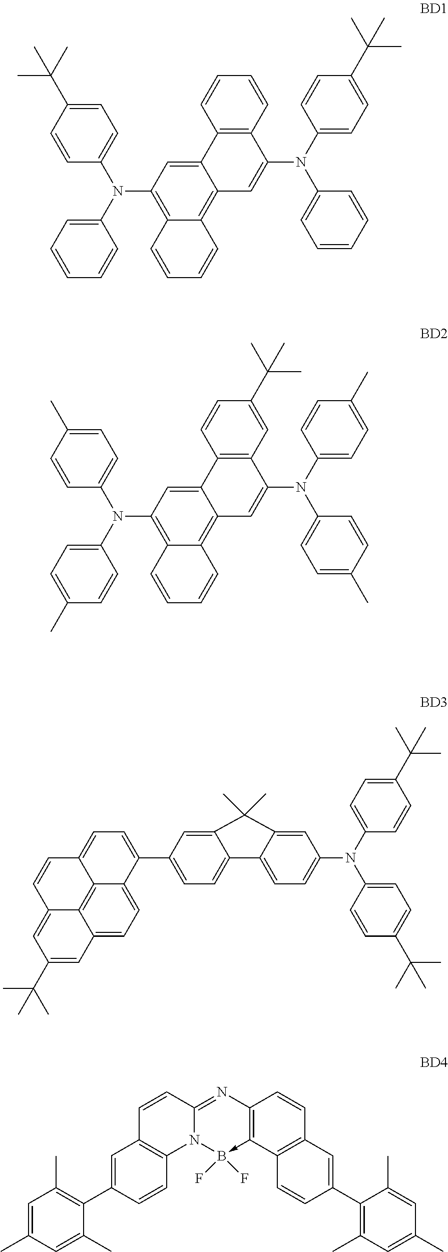

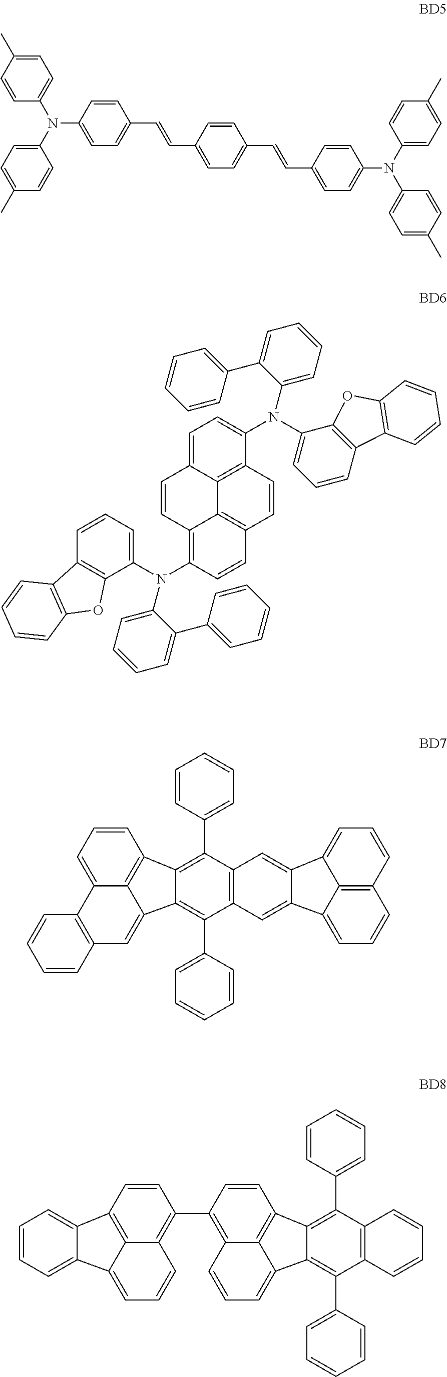

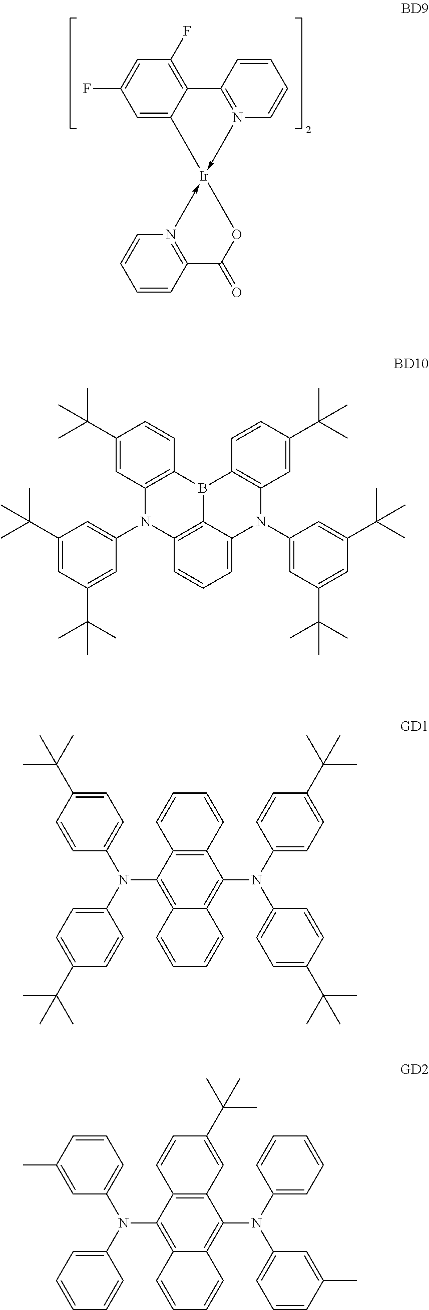

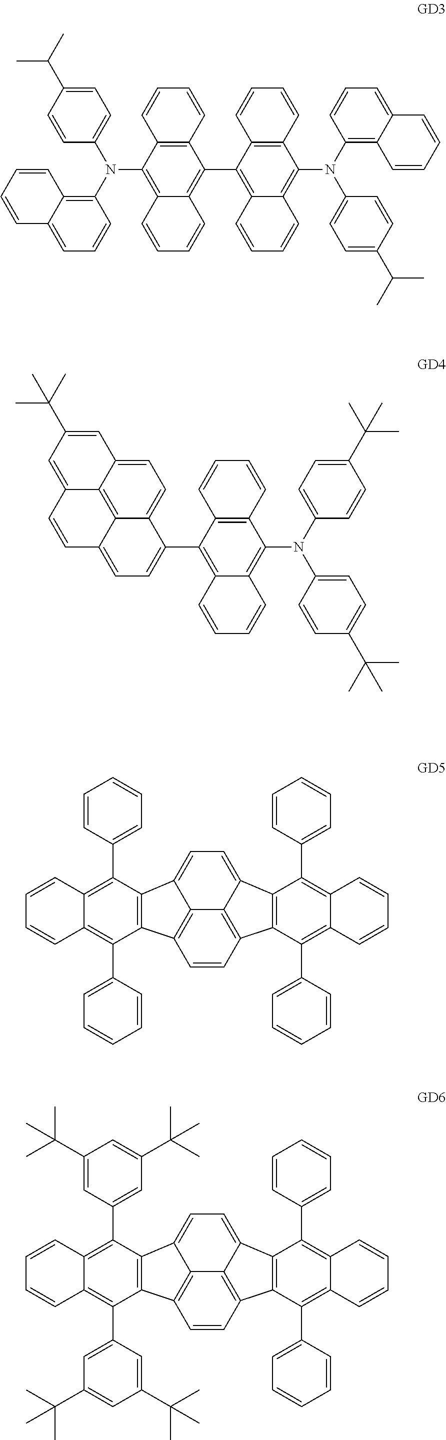

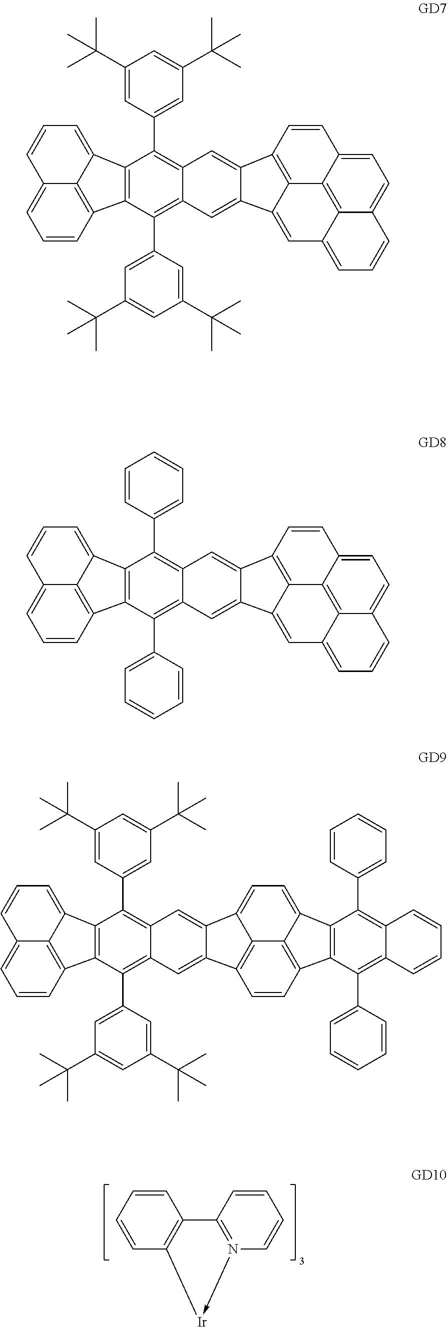

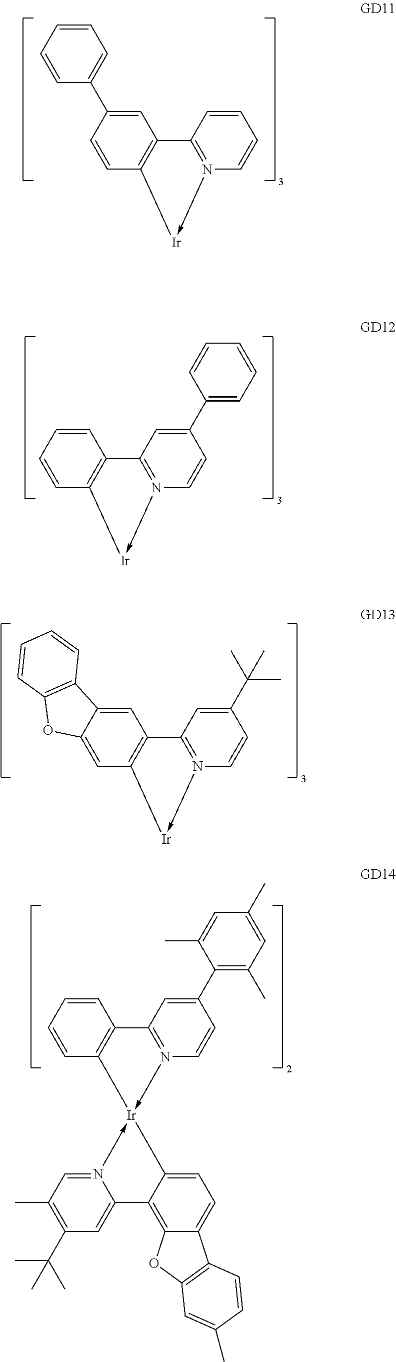

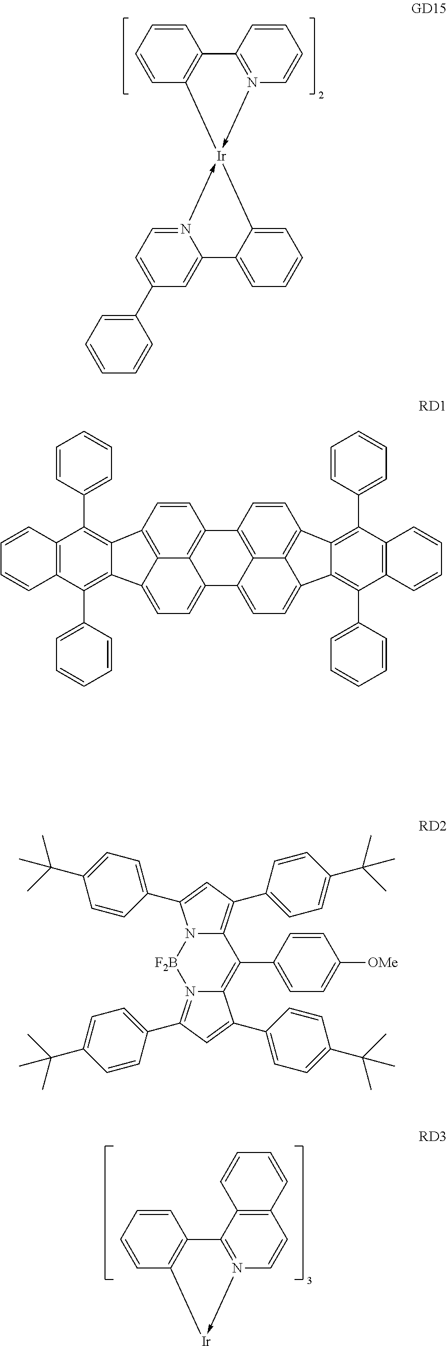

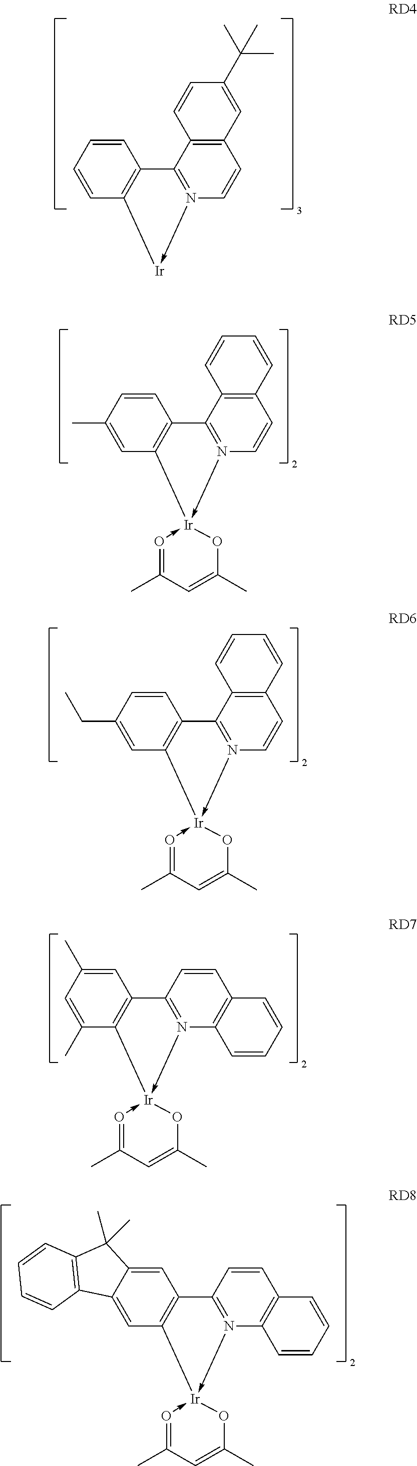

Examples of the light-emitting layer host or assist material contained in the light-emitting layer include aromatic hydrocarbon compounds and their derivatives, carbazole derivatives, dibenzofuran derivatives, dibenzothiophene derivatives, triazine derivatives, organoaluminum complexes such as tris(8-quinolinolato)aluminum, organoberyllium complexes, and polymeric compounds, such as polyphenylene derivatives, polyphenylene vinylene derivatives, polyfluorene derivatives, polyvinylcarbazole derivatives, and their copolymers or mixtures.

Specific examples of compounds that can be used as the light-emitting layer host or assist material in the light-emitting layer include, but are not limited to, the following:

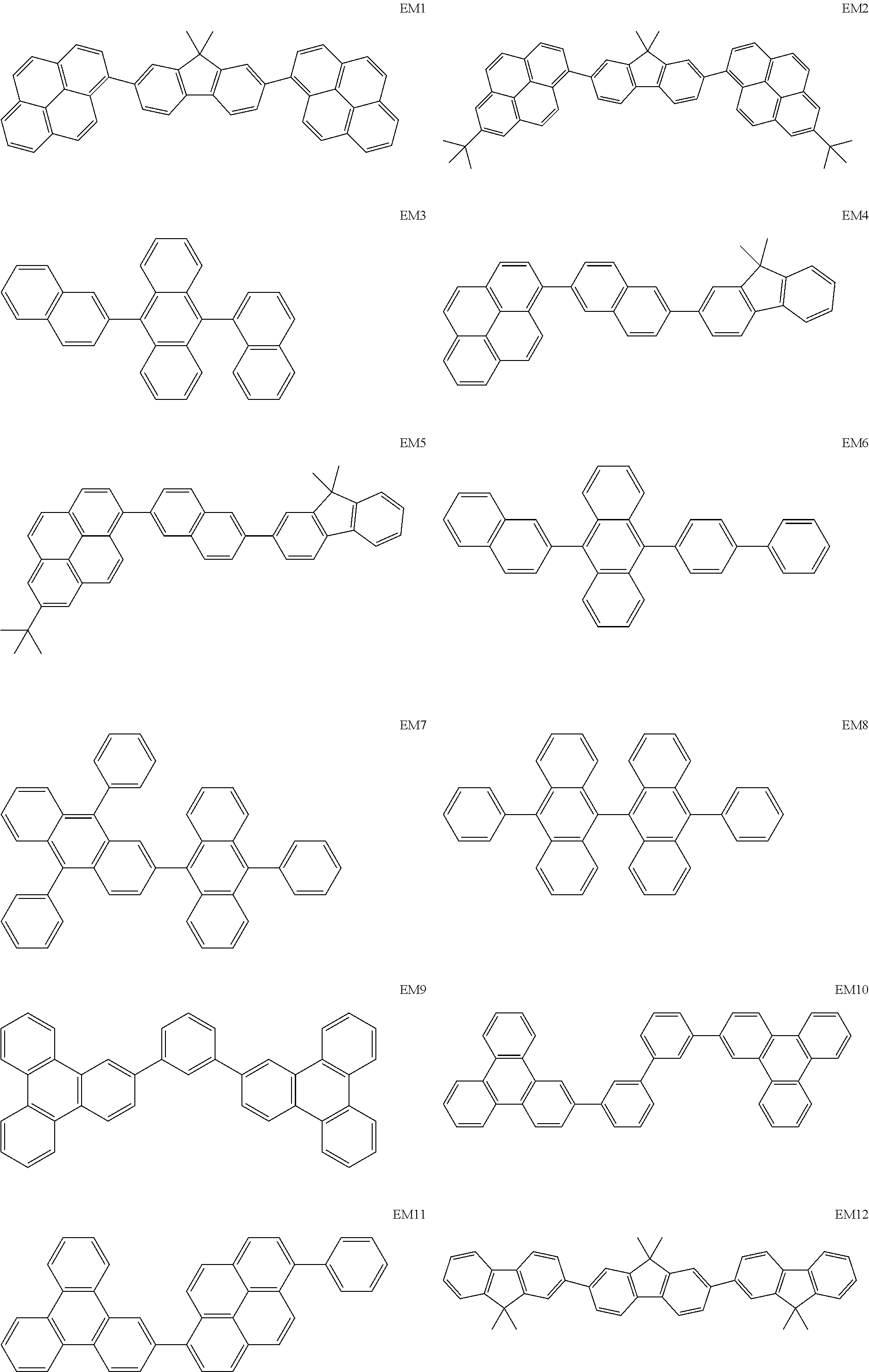

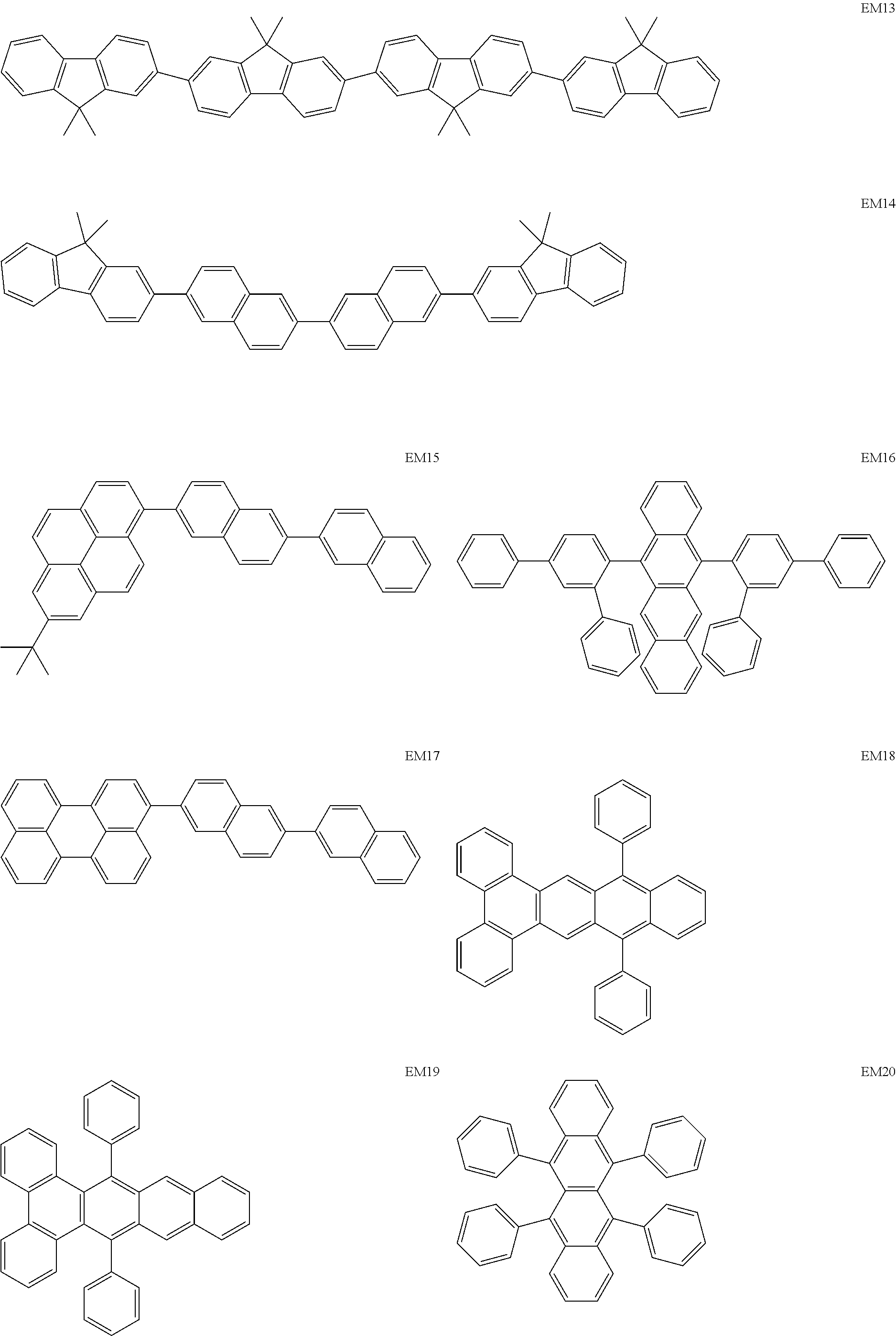

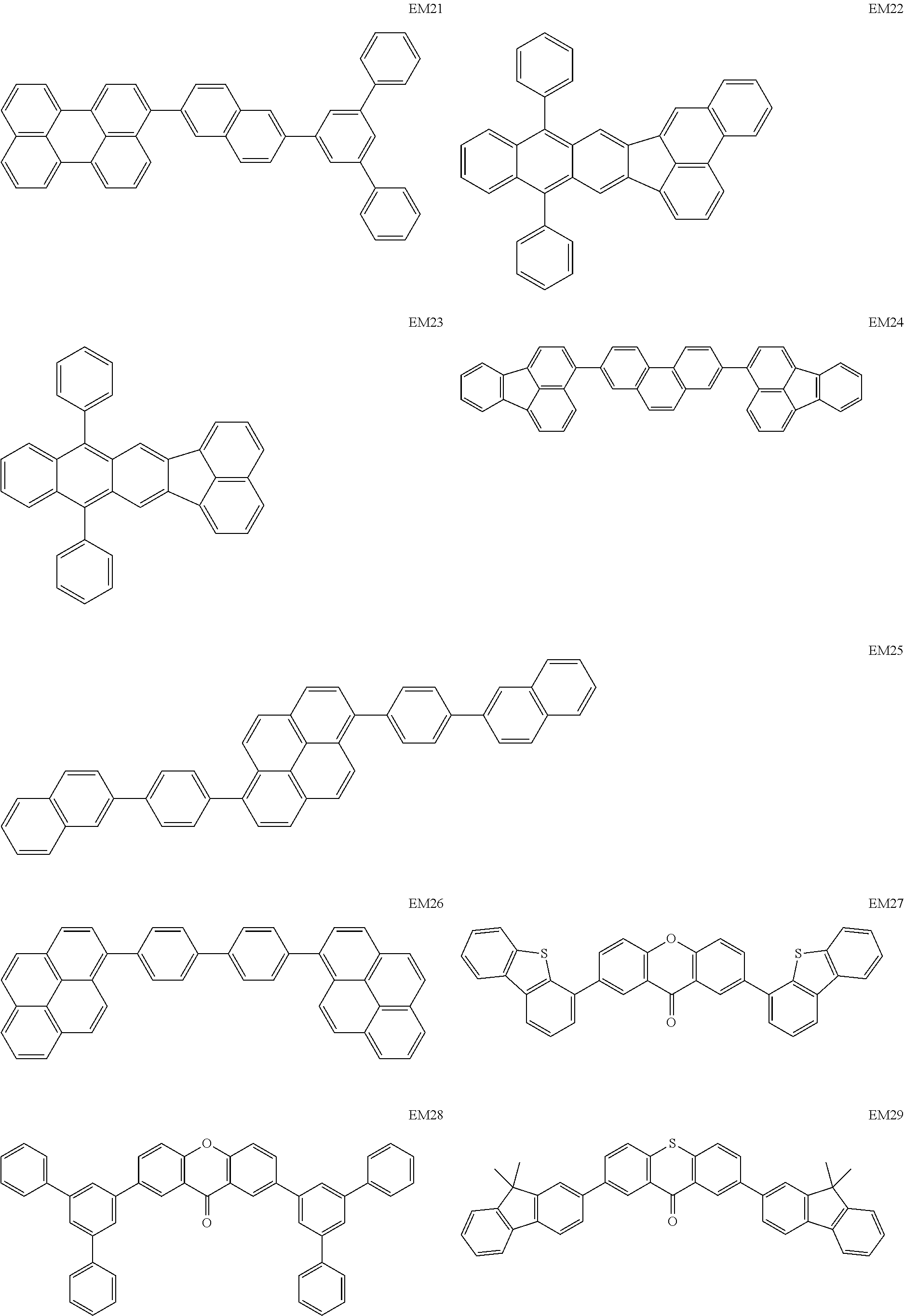

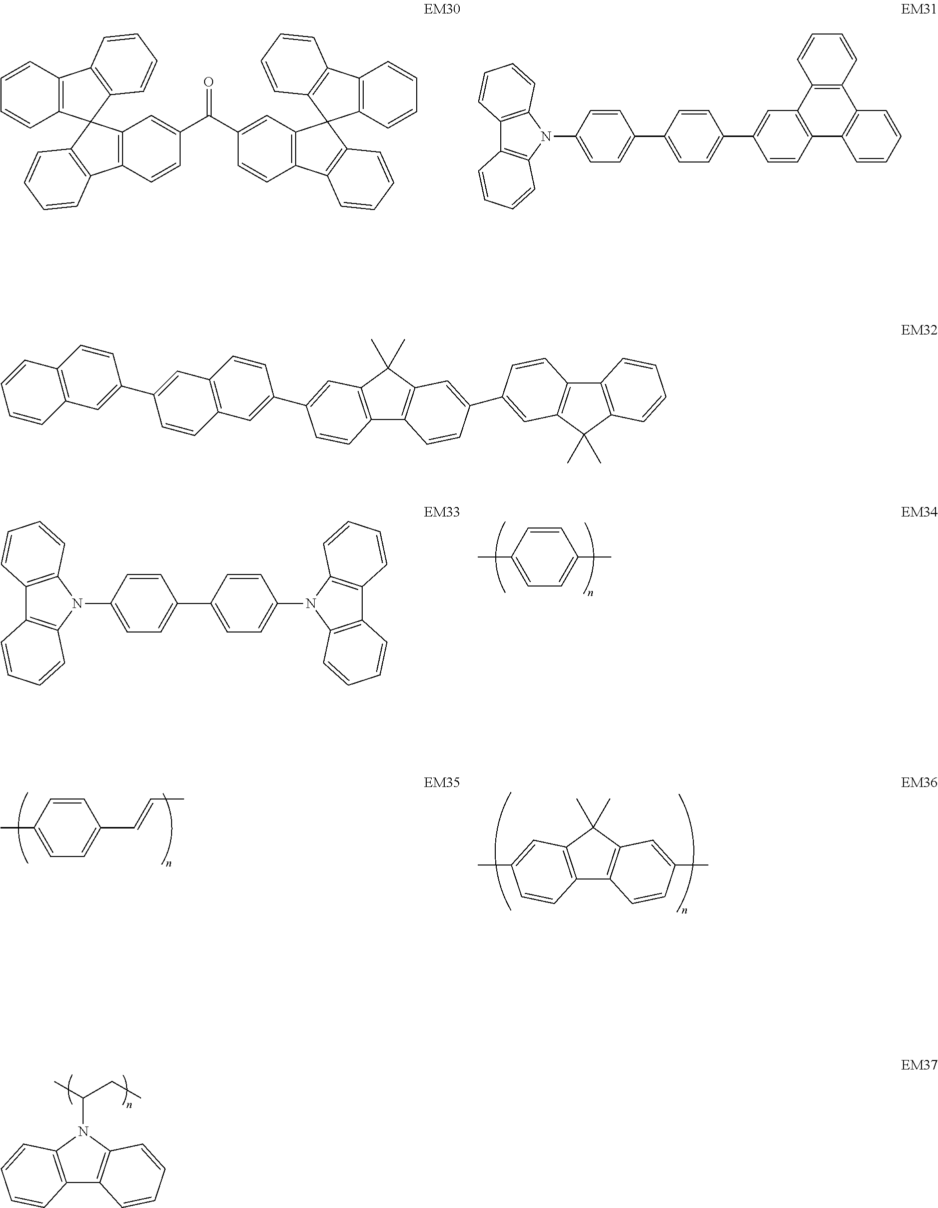

The electron transporting material can be selected arbitrarily from the compounds capable of transporting electrons injected from the cathode to the light-emitting layer and is selected in view of, for example, the balance with the hole mobility of the hole transporting material. Materials capable of transporting electrons include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused ring compounds (e.g., fluorene derivatives, naphthalene derivatives, chrysene derivatives, anthracene derivatives, and so forth) The above electron transporting materials are also suitably used in the hole blocking layer.

Specific examples of the compounds that can be used as the electron transporting material include, but are of course not limited to, the following:

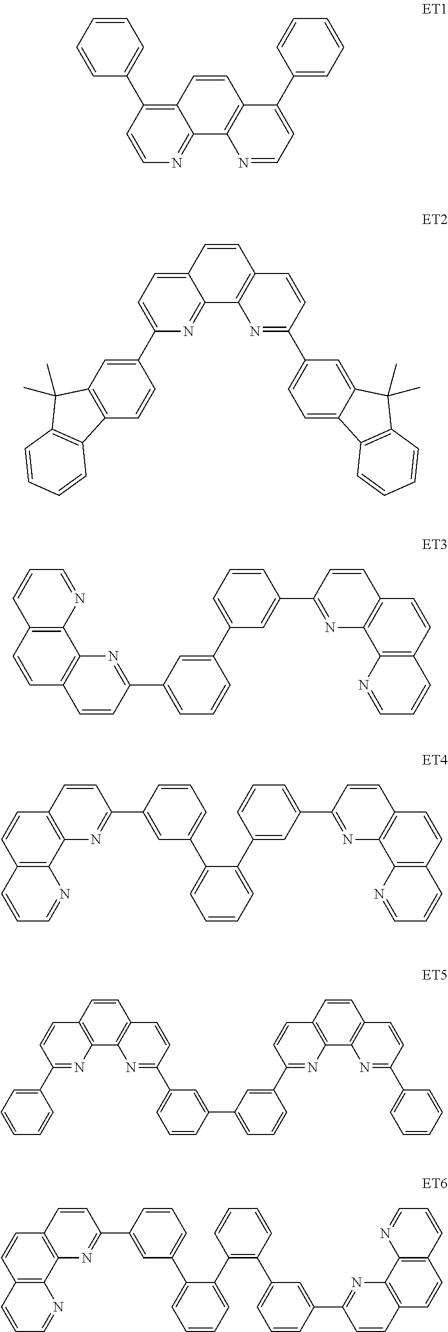

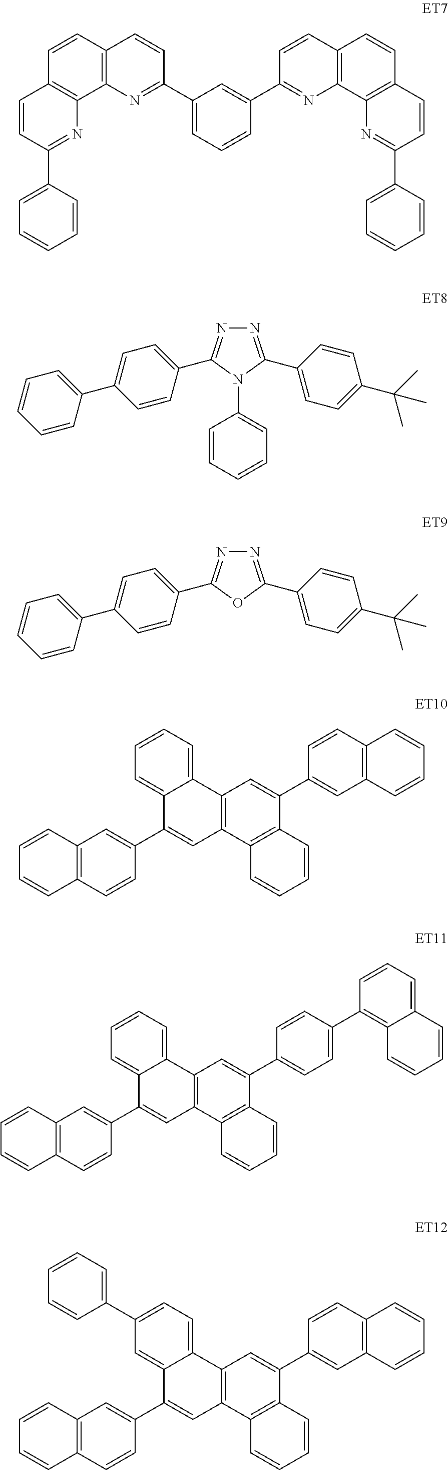

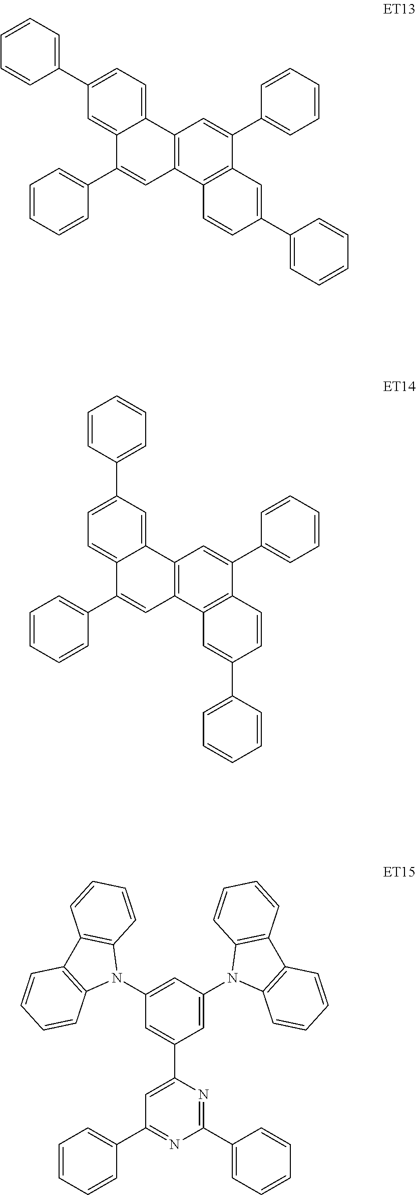

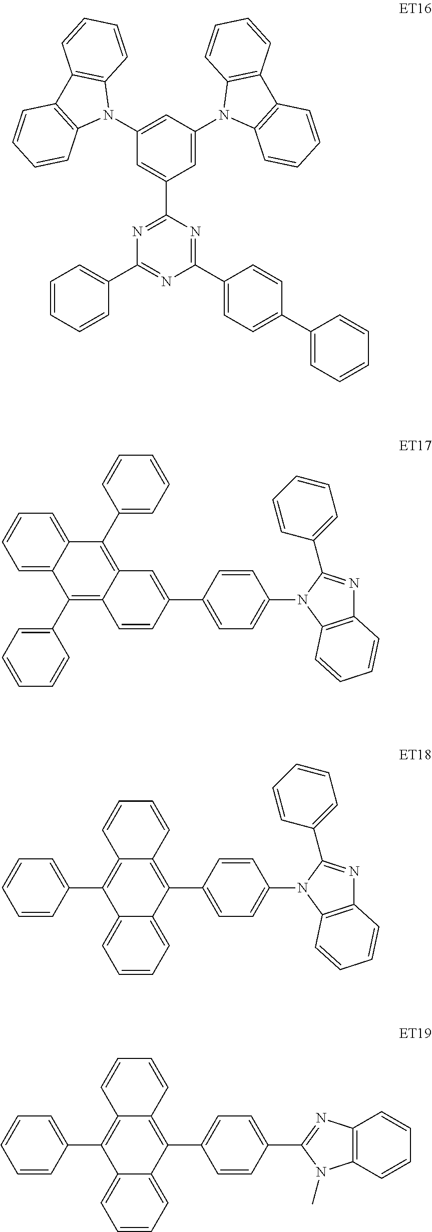 [SMILES: c1ccc(-c2ccc(-c3nc(-c4ccccc4)nc(-c4cc(-n5c6ccccc6c6ccccc65)cc(-n5c6ccccc6c6ccccc65)c4)n3)cc2)cc1 ; c1ccc(-c2c3ccccc3c(-c3ccccc3)c3cc(-c4ccc(-n5c(-c6ccccc6)nc6ccccc65)cc4)ccc23)cc1 ; c1ccc(-c2c3ccccc3c(-c3ccc(-n4c(-c5ccccc5)nc5ccccc54)cc3)c3ccccc23)cc1 ; Cn1c(-c2ccc(-c3c4ccccc4c(-c4ccccc4)c4ccccc34)cc2)nc2ccccc21]

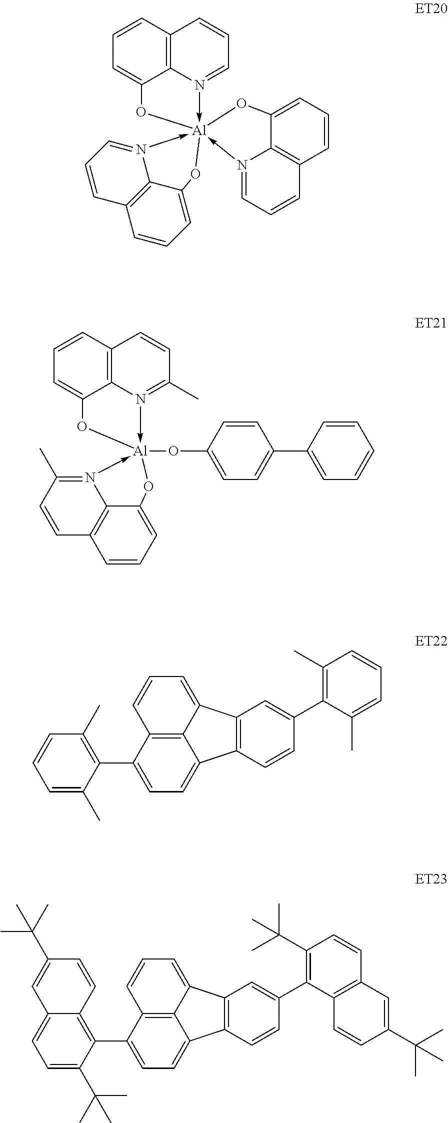

The electron injecting material can be selected arbitrarily from the compounds that can easily inject electrons from the cathode and is selected in view of, for example, the balance with hole injection. N-type dopants and reducing dopants can also be used as the electron injecting material. Examples include alkali metal-containing compounds such as lithium fluoride, lithium complexes such as lithium quinolinol, benzoimidazolidene derivatives, imidazolidene derivatives, fulvalene derivatives, and acridine derivatives.

The organic compound layers of the organic light-emitting element according to the present disclosure may be formed in, but not limited to, a dry process or a wet process. For the dry process, vacuum vapor deposition, ionized vapor deposition, sputtering, or using plasma may be applied, for example. In the wet process, the materials are dissolved in an appropriate solvent, and a known coating method may be applied (e.g. spin coating, casting, microgravure coating, gravure coating, bar coating, roll coating, wire bar coating, dip coating, spray coating, screen printing, flexography, offset printing, ink jet printing, capillary coating, or nozzle coating). In particular, vacuum vapor deposition, ionized vapor deposition, ink jet printing, nozzle coating, and the like are suitable for manufacturing large-area organic light-emitting elements.

The preferred thickness of each layer of the organic light-emitting element is generally 1 nm to 10 μm. In particular, the thickness of the light-emitting layer of the organic compound layers is preferably 10 nm to 100 nm to obtain effective emission characteristics.

### Substrate

The organic light-emitting element is provided by forming a first electrode, organic compound layers, and a second electrode on an insulating layer provided on a substrate. The second electrode may be provided with a protective layer, a color filter, and the like thereon. For forming the color filter, a planarizing layer may be formed between the protective layer and the color filter. The planarizing layer may be made of acrylic resin or the like. One of the first and second electrodes can be an anode, and the other is a cathode.

The substrate may be made of quartz, glass, silicon wafer, resin, metal, or the like. A switching element, such as a transistor, and wires may be arranged on the substrate, and over which an insulating layer is formed. The insulating layer may be made of any material, provided that contact holes can be formed for wiring to ensure electrical conduction to the anode, and that insulation can be ensured from unconnected wires. For example, polyimide or similar resins, silicon oxide, silicon nitride, or the like may be used.

### Electrodes

The organic light-emitting element uses a first electrode and a second electrode, and one of the electrodes is used as an anode, and the other is used as a cathode. The electrode with a higher potential when an electric field is applied in the direction in which the organic light-emitting element emits light is the anode, and the other is the cathode. Also, the electrode that supplies holes to the light-emitting layer is the anode, and the electrode that supplies electrons is the cathode.

The material of the anode desirably has as high a work function as possible. Examples of such a material include simple metals, such as gold, platinum, silver, copper, nickel, palladium, cobalt, selenium, vanadium, and tungsten, mixtures containing simple metals or alloys formed by combining those metals, and metal oxides, such as tin oxide, zinc oxide, indium oxide, indium tin oxide (ITO), and indium zinc oxide. Electrically conductive polymers, such as polyaniline, polypyrrole, and polythiophene, may also be used. These electrode materials may be used individually or in combination. The anode may be composed of a single layer or a plurality of layers.

When the anode is used as a reflection electrode, for example, chromium, aluminum, silver, titanium, tungsten, molybdenum, or an alloy or multilayer composite of these metals may be used. When the anode is used as a transparent electrode, an electrically conductive transparent metal oxide layer of, for example, indium tin oxide (ITO) or indium zinc oxide may be used, but the material is not limited to these. Photolithography technology can be used to form the electrode.

The material of the other electrode, that is, the cathode, desirably has a low work function. Examples of such a material include alkali metals, such as lithium; alkaline-earth metals, such as calcium; other simple metals, such as aluminum, titanium, manganese, silver, lead, and chromium; and mixtures containing these simple metals. Alternatively, alloys formed by combining these simple metals may be used. Examples of such an alloy include magnesium-silver, aluminum-lithium, aluminum-magnesium, silver-copper, and zinc-silver. Metal oxides, such as indium tin oxide (ITO), may also be used. These electrode materials may be used individually or in combination. The cathode may be composed of a single layer or a plurality of layers. In particular, silver is preferably used, and silver alloy is more preferable because it reduces the aggregation of silver. Any proportion in the alloy is acceptable as long as the aggregation of silver can be reduced. For example, it may be 1:1.

The cathode may be, but is not limited to, an electrically conductive oxide layer, such as indium tin oxide (ITO), to provide a top emission element, or a reflection electrode, such as aluminum, to provide a bottom emission element.

The cathode may be formed by any method without limitation, but direct current or alternating current sputtering is more suitable because it provides good film coverage and easily reduces resistance.

### Protective Layer

A protective layer may be provided over the cathode. For example, a glass sheet with a moisture absorbent may be bonded onto the cathode to reduce the penetration of water or the like into the organic compound layers, thus reducing the occurrence of display failure. In another disclosure, a passivation film of silicon nitride or the like may be provided over the cathode to reduce the penetration of water or the like into the organic compound layers. For example, after being formed, the cathode is transported to another chamber with a vacuum maintained, and a 2 μm-thick silicon nitride film may be deposited by CVD to form a protective layer. After deposition by CVD, a protective layer may be formed by atomic layer deposition (ALD).

### Color Filter

A color filter may be provided on the protective layer. For example, a color filter that allows for the size of the organic light-emitting element is provided on a substrate and then bonded to another substrate provided with the organic light-emitting element. Alternatively, a color filter may be patterned on the protective layer described above by photolithography technology. The color filter may be made of a polymer.

### Planarizing Layer

A planarizing layer may be disposed between the color filter and the protective layer. The planarizing layer may be made of an organic compound, which may be low molecular weight or polymeric but is preferably polymeric.

The planarizing layer may be provided on each of the upper and lower sides of the color filter, and the material may be the same or different. Specifically, examples include polyvinylcarbazole resin, polycarbonate resin, polyester resin, ABS resin, acrylic resin, polyimide resin, phenolic resin, epoxy resin, silicone resin, and urea resin.

### Opposing Substrate

An opposing substrate may be disposed on the planarizing layer. The opposing substrate is located in a position opposing the aforementioned substrate and is, therefore, called the opposing substrate. The opposing substrate may be made of the same material as the aforementioned substrate. When the aforementioned substrate is a first substrate, the opposing substrate may be a second substrate.

Structure of Device with Organic Light-Emitting Element

### Pixel Circuit

A light-emitting device including the organic light-emitting element disclosed herein may include a pixel circuit connected to the light-emitting element. The pixel circuit may be a type of active matrix that independently controls a first light-emitting element and a second light-emitting element for emission. The active matrix circuit may be controlled by either voltage programming or current programming. The driving circuit includes a pixel circuit for each pixel. The pixel circuit may include a transistor to control the organic light-emitting element and the luminance of emission from the light-emitting element, a transistor to control emission timing, a capacitor to hold the gate voltage of the transistor that controls the luminance of emission, and a transistor for connection to the GND but not via the light-emitting element.

The light-emitting device includes a display region and a peripheral region around the display region. The display region has pixel circuits, and the peripheral region has a display control circuit.

In the transistor of the pixel circuit, the mobility may be lower than that in the transistor of the display control circuit.

The transistor of the pixel circuit may have a current-voltage characteristic with a smaller slope than the transistor of the display control circuit. The slope of the current-voltage characteristic can be determined using what is called Vg-Ig characteristics.

The transistor of the pixel circuit is the transistor connected to an organic light-emitting element, for example, a first organic light-emitting element.

### Pixel

The light-emitting device including the organic light-emitting element disclosed herein has a plurality of pixels. Each pixel includes sub-pixels that emit different colors from each other. Sub-pixels may have their respective RGB emission colors.

The pixels emit light from a region called a pixel aperture. The pixel aperture may be 15 μm or less and may be 5 μm or more. More specifically, it may be 11 μm, 9.5 μm, 7.4 μm, 6.4 μm, or so forth. The distance between sub-pixels may be 10 μm or less, specifically, 8 μm, 7.4 μm, or 6.4 μm.

The pixels may be arranged in a known array in plan view. For example, the pixels may be arranged in striped array, a delta array, pentile array, or a Bayer array. The sub-pixels may have any known shape in plan view. For example, the shape may be quadrilateral, such as rectangular or rhombic, hexagonal, and so forth. Of course, the shape may not be an exact figure, and, for example, a shape close to a rectangle is considered rectangular. The shape of sub-pixels and the pixel arrangement may be combined.

### Applications of Organic Light-Emitting Element

The organic light-emitting element disclosed herein can be used as a component of a display device or a lighting device. In addition, the organic light-emitting element may be used as an exposure light source of an electrophotographic image forming apparatus, a backlight of a liquid crystal display device, or a light-emitting device including a white light source provided with a color filter.

The display device may be used in an image information processing apparatus that includes an image input section to which image information is input from an area CCD, a linear CCD, a memory card, or the like, an information processing section in which the inputted information is processed, and a display section on which the inputted information is displayed.

The display section of an imaging device or an ink jet printer may have a function as a touch panel. The touch panel function may be operated by, but not limited to, using infrared, capacitance, a resistive film, or electromagnetic induction. Also, the display device may be used as a display section of a multifunctional printer.

The display device according to the present disclosure will now be described with reference to drawings.

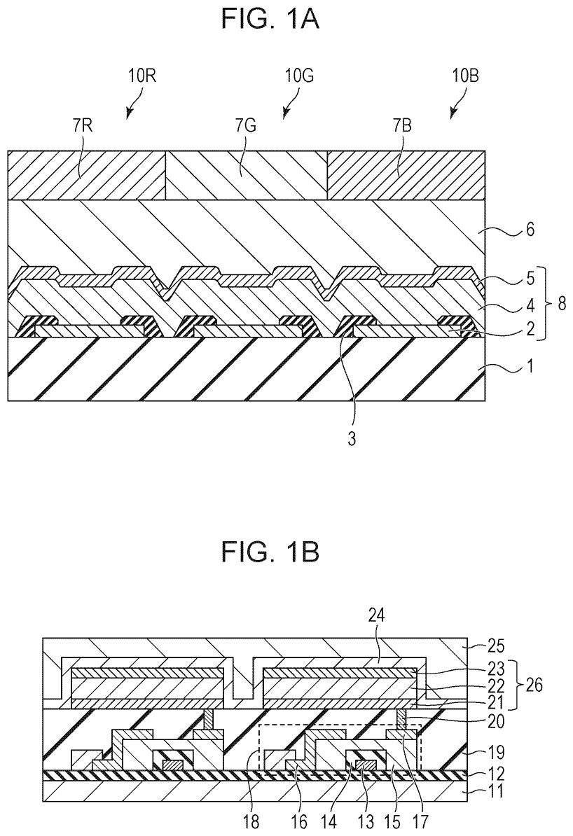

FIGS. 1A and 1B are each a schematic sectional view of a display device including organic light-emitting elements disclosed herein and transistors connected to the respective organic light-emitting elements.

FIG. 1A depicts an example of a pixel that is a component of the display device according to the present disclosure. The pixel includes sub-pixels 10. The sub-pixels are categorized into 10R, 10G, and 10B depending on the emission color. Emission colors may be identified by the wavelength of the light emitted from the light-emitting layer, or color filters or the like may selectively transmit the light emitted from the sub-pixels or convert the color of the light. Each sub-pixel includes, on an interlayer insulating layer 1, a first electrode 2, which is a reflection electrode, an insulating layer 3 covering the edge of the first electrode 2, an organic compound layer 4 covering the first electrode 2 and the insulating layer 3, a second electrode 5, a protective layer 6, and a color filter 7. The first electrode 2, the organic compound layer 4, and the second electrode 5 constitutes an organic light-emitting element.

Transistors and capacitor elements may be disposed under or within the interlayer insulating layer 1. The transistors and the respective first electrodes 2 may be electrically coupled through a contact hole or the like not shown in the figure.

The insulating layer 3 is also called a bank or pixel isolation film. The insulating layer covers the edges of the first electrodes 2 and surrounds the first electrodes 2. The portion of each first electrode not covered with the insulating layer 3 is in contact with the organic compound layer 4 to act as a light-emitting region.

The second electrode 5 may be transparent, reflective, or semitransparent.

The protective layer 6 reduces water permeation into the organic compound layer 4. The protective layer 6, which is illustrated as a single layer, may include a plurality of layers. Each layer may include an inorganic compound layer or an organic compound layer.

Color filters 7 are categorized into 7R, 7G, and 7B depending on the color. The color filters may be formed on a planarizing layer not shown in the figure. Also, a resin protective layer, not shown in the figure, may be formed over the color filters. The color filters may be formed on the protective layer 6. Alternatively, the color filters may be formed on an opposing substrate such as a glass substrate and then bonded together.

The display device depicted in FIG. 1B includes organic light-emitting elements 26 and TFTs 18, which are an example of transistors. Specifically, a substrate 11 made of glass, silicon, or the like is provided with an insulating layer 12 thereon, and TFTs 18 including a gate electrode 13, a gate insulating film 14, a semiconductor layer 15, a drain electrode 16, and a source electrode 17 are disposed on the insulating layer 12. An insulating film 19 is formed over the TFTs 18, and the anode 21 and the source electrode 17, which are components of the organic light-emitting element 26, are connected to each other through a contact hole 20 formed in the insulating film 19.

The electrical coupling between the electrodes of the organic light-emitting element 26 (anode 21, cathode 23) and the electrodes of the TFT (source electrode 17, drain electrode 16) is not limited to the manner illustrated in FIG. 1B. In other words, either the anode 21 or the cathode 23 is electrically coupled to either the source electrode 17 or the drain electrode 16. A TFT refers to a thin film transistor.

A first protective layer 24 and a second protective layer 25 are disposed over the cathodes 23 to reduce the deterioration of the organic light-emitting elements.

In the organic light-emitting element 26 according to the present disclosure, the luminance of the emission is controlled by the TFT 18, and a plurality of such organic light-emitting elements 26 are arranged in a plane so that the emission luminances of the respective organic light-emitting elements are involved in displaying images.

Although the display device depicted in FIG. 1B uses transistors as switching elements, other switching elements may be used instead of transistors.

The transistors used in the display device in FIG. 1B are not limited to those having an active layer on an insulating surface of the substrate and may be transistors using monocrystalline silicon wafer. The active layer may be made of non-monocrystalline silicon, such as amorphous silicon or microcrystalline silicon, or a non-monocrystalline oxide semiconductor, such as indium zinc oxide or indium gallium zinc oxide.

Alternatively, the switching elements may be transistors made of a low-temperature polysilicon or an active matrix driver formed on a substrate such as a Si substrate. The phrase “on a substrate” may also mean within the substrate. Whether providing transistors within a substrate or using TFTs depends on the size of the display section. For example, in the case of about 0.5 inch in size, providing organic light-emitting elements on a silicon substrate is preferred. To be formed within the substrate means that the transistors are formed by working a Si substrate or a similar substrate itself. In other words, the presence of transistors within a substrate can mean that the substrate and the transistors are formed in one body.

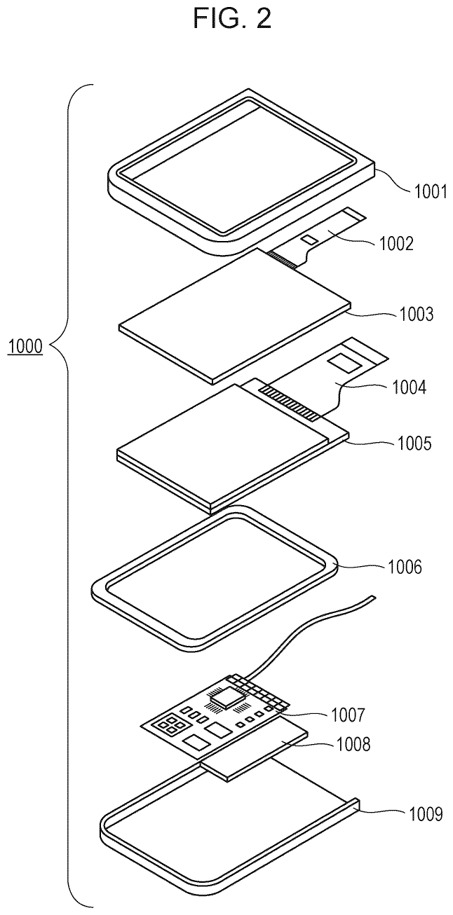

FIG. 2 is a schematic illustrative representation of a display device according to the present disclosure. The display device 1000 includes a touch panel 1003, a display panel 1005, a frame 1006, a circuit board 1007, and a battery 1008 between an upper cover 1001 and a lower cover 1009. The touch panel 1003 and the display panel 1005 are connected to flexible printed circuits FPCs 1002 and 1004, respectively. Transistors are printed on the circuit board 1007. The battery 1008 is not necessarily provided unless the display device is for mobile use, and, for mobile use, the battery may be located in another position.

The display device according to the present disclosure may include red, green, and blue color filters. The red, green, and blue color filters may be arranged in a delta array.

The display device according to the present disclosure may be used in the display section of a mobile terminal. In this instance, the display device may have both a displaying function and an operational function. The mobile terminal may be a cellular phone, such as a smartphone, a tablet PC, a head-mounted display, or the like.

The display device according to the present disclosure may be used as a display section of an imaging device including an optical system having a plurality of lenses and an imaging element to receive light that has passed through the optical system. The imaging device may have a display section that displays information obtained by the imaging element. The display section may be exposed to the outside of the imaging device or may be disposed within a finder. The imaging device may be a digital camera or a digital video camera.

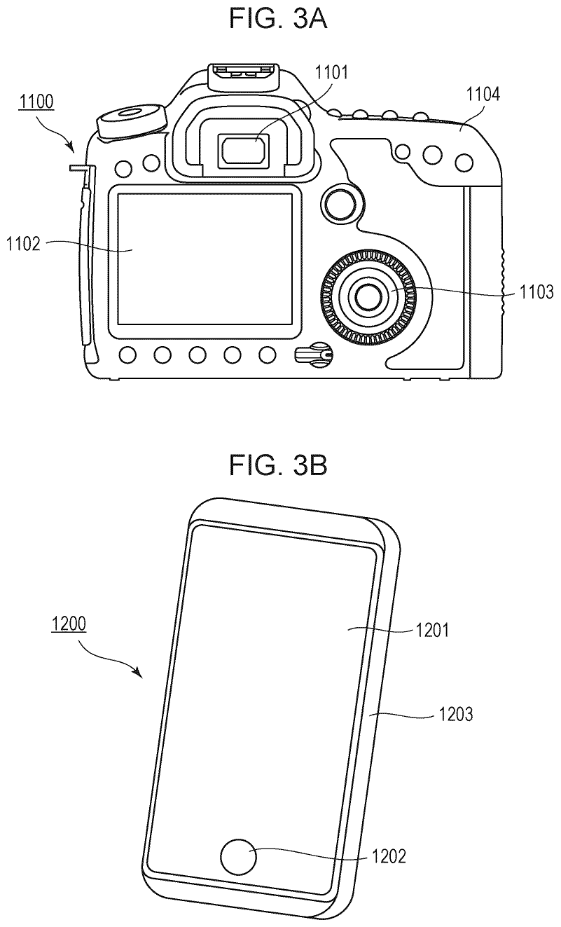

FIG. 3A is a schematic illustrative representation of an imaging device according to the present disclosure. The imaging device 1100 includes a viewfinder 1101, a rear display 1102, an operational section 1103, and a housing 1104. The viewfinder 1101 may include the display device according to the present disclosure. In this instance, the display device may display not only images to be taken but also environmental information, imaging instructions, or the like. The environmental information may include the intensity and direction of external light, the speed at which the subject moves, and the possibility that an object hides the subject.

Since the appropriate timing for taking an image is only a short period, it is desirable to display information as quickly as possible. Accordingly, a display device that includes the organic light-emitting element disclosed herein is preferably used. This is because the organic light-emitting element responds quickly. The display device using the organic light-emitting element is more suitably used than liquid crystal display devices in apparatuses required to display information quickly.

The imaging device 1100 includes an optical system (not shown). The optical system includes a plurality of lenses and forms an image on the imaging element in the housing 1104. The focus can be adjusted by adjusting the relative positions of the plurality of lenses. This operation may be automatically performed. The imaging device may be called a photoelectric conversion device.

The photoelectric conversion device may take images by detecting differences from a previous image or cutting an image out of continuously recorded images, but not by taking images one by one.

FIG. 3B is a schematic illustrative representation of an electronic apparatus according to the present disclosure. The electronic apparatus 1200 includes a display section 1201, an operational section 1202, and a housing 1203. The housing 1203 may contain a circuit, a printed board having the circuit, a battery, and a communication section. The operational section 1202 may be a button or a touch panel responder. The operational section may have a biometrically authenticating function for recognizing the fingerprint and releasing the lock. An electronic apparatus including a communication section may be referred to as a communication apparatus. The electronic apparatus may further include a lens and an imaging element to function as a camera. Images taken by the function as a camera are displayed on the display section. Electronic apparatuses include smartphones and laptop PCs.

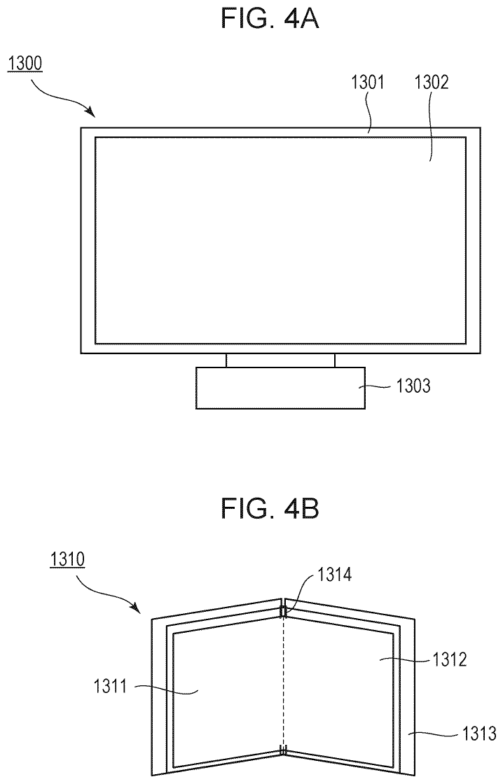

FIGS. 4A and 4B are each a schematic illustrative representation of a display device according to the present disclosure. FIG. 4A illustrates a display device such as a TV monitor or a PC monitor. The display device 1300 includes a frame 1301 and a display section 1302. The display section 1302 includes the light-emitting device according to the present disclosure.

A base 1303 supporting the frame 1301 and the display section 1302 is also included. The base 1303 is not limited to the form illustrated in FIG. 4A. The lower side of the frame 1301 may serve as the base.

The frame 1301 and the display section 1302 may be curved. The radius of curvature may be 5000 mm to 6000 mm.

FIG. 4B is a schematic illustrative representation of a display device according to another form of the present disclosure. The display device 1310 depicted in FIG. 4B is foldable and is, thus, what is called a foldable display device. The display device 1310 includes a first display section 1311, a second display section 1312, and a housing 1313 and has folding points 1314. The first display section 1311 and the second display section 1312 each may include the light-emitting device according to the present disclosure. The first display section 1311 and the second display section 1312 may constitute a seamless one-piece display device. The first display section 1311 and the second display section 1312 can be divided at the folding points. The first display section 1311 and the second display section 1312 may display different images from each other, or a single image may be displayed on a set of the first and second display sections.

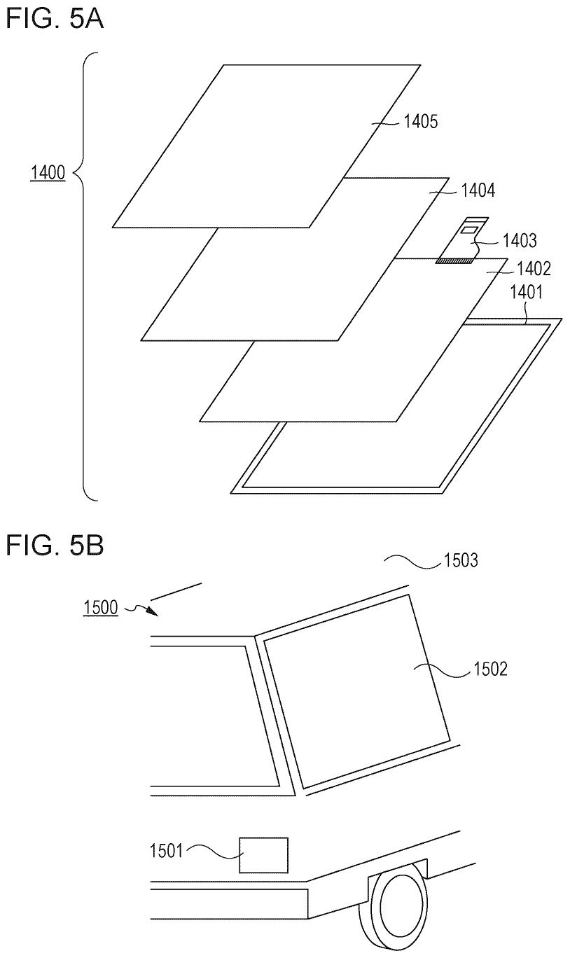

FIG. 5A is a schematic illustrative representation of a lighting device according to the present disclosure. The lighting device 1400 includes a housing 1401, a light source 1402, a circuit board 1403, an optical filter 1404, and a light diffusing section 1405. The light source 1402 includes the organic light-emitting element disclosed herein. The optical filter 1404 may be a filter to improve the color rendering properties of the light source. The light diffusing section 1405 diffuses light emitted from the light source 1402 effectively so that the light reaches a wide area for, for example, lighting up. The optical filter 1404 and the light diffusing section 1405 may be disposed on the light emitting side of the lighting device. A cover may be provided at an outermost portion, if necessary.

The lighting device illuminates, for example, a room. The lighting device may emit white light, neutral white light, or any other color light of the colors from blue to red. The lighting device may include a dimmer circuit that dims the light. The lighting device includes the organic light-emitting element disclosed herein and a power supply circuit connected to the organic light-emitting element. The power supply circuit converts alternating voltage to direct voltage. White has a color temperature of 4200 K and neutral white has a color temperature of 5000 K. The lighting device may include a color filter.

The lighting device according to the present disclosure may include a heat radiation section. The heat radiation section is intended to dissipate heat from the device to the outside and may be made of, for example, a metal having a high specific heat or liquid silicone.

FIG. 5B is a schematic illustrative representation of an automobile that is an example of the movable apparatus according to the present disclosure. The automobile has a tail lamp that is an example of lighting fixtures. The automobile 1500 has a tail lamp 1501, and the tail lamp may be such that it turns on when braking operation or the like is performed.

The tail lamp 1501 includes the organic light-emitting element disclosed herein. The tail lamp may include a protective member that protects the organic light-emitting element. The protective member may be made of any transparent material as long as it has high strength to some extent, preferably polycarbonate or the like. The polycarbonate may be mixed with a furandicarboxylic acid derivative, an acrylonitrile derivative, or the like.

The automobile 1500 may include a car body 1503 and a window 1502 attached to the car body. The window may be a transparent display unless it is intended to be used to check the front and rear of the automobile. The transparent display may include the organic light-emitting element disclosed herein. In this instance, the component members of the organic light-emitting element, such as electrodes, are made of transparent materials.

In an disclosure, the movable apparatus may be a ship, an aircraft, a drone, or the like. The movable apparatus may include an apparatus body and a lighting fixture provided at the apparatus body. The lighting fixture emits light to notify the position of the apparatus body. The lighting fixture includes the organic light-emitting element disclosed herein.

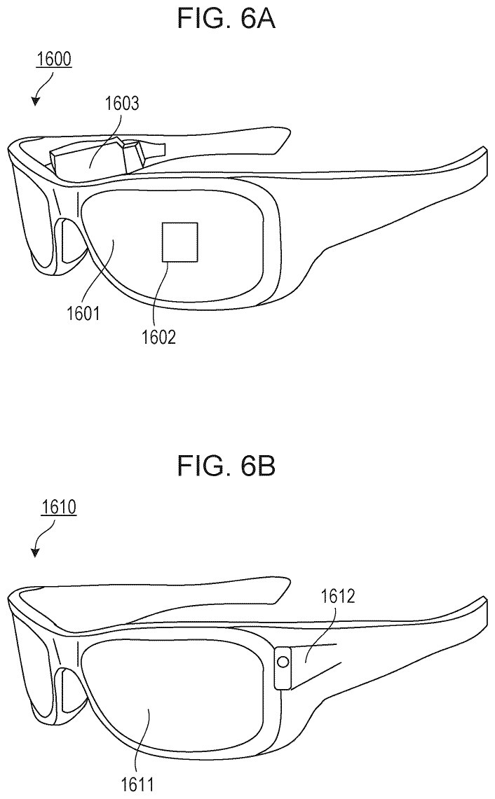

Examples of the application of the display device according to the above disclosures will now be described with reference to FIGS. 6A and 6B. The display device may be applied to systems that can be worn as a wearable device, such as smart glasses, an HMD, and or smart contact lenses. An imaging display device used in such an application includes an imaging device capable of converting visible light into electrical energy and a display device capable of emitting visible light.

FIG. 6A illustrates glasses 1600 (smart glasses) according to an application. The glasses 1600 are provided with an imaging device 1602, such as a CMOS sensor or a SPAD, on the front surface of the lenses 1601. Also, a display device according to an disclosure described above is provided on the rear surface of the lenses 1601.

The glasses 1600 further include a controller 1603. The controller 1603 functions as a power supply to supply power to the imaging device 1602 and the display device according to an disclosure. The controller 1603 also controls the operations of the imaging device 1602 and the display device. In the lenses 1601, an optical system is formed to focus light on the imaging device 1602.

FIG. 6B illustrates glasses 1610 (smart glasses) according to an application. The glasses 1610 include a controller 1612, and the controller 1612 includes an imaging device corresponding to the imaging device 1602 in FIG. 6A and a display device. The lenses 1611 have an optical system that projects light from the imaging device in the controller 1612 and the display device, and images are projected onto the lenses 1611. The controller 1612 functions as a power supply to supply power to the imaging device and the display device and also controls the operations of the imaging device and the display device. The controller may have a sight line detector that detects the wearer's line of sight. Infrared light may be used to detect the line of sight. Infrared light is emitted from an infrared emission section to an eyeball of the user gazing at the displayed image. An imaging section with a light receiving element detects the reflection of the infrared light emitted from the eyeball, thus obtaining a captured image of the eyeball. The deterioration of image quality is reduced by providing a reducing device that reduces the light in plan view to the display section from the infrared emission section.

The user's line of sight to the displayed image is detected from the captured image of the eyeball obtained by capturing the infrared light. Known techniques can be applied to detect the line of sight using a captured image of the eyeball. For example, a sight line detection method based on the Purkinje image formed by the reflection of irradiation light at the cornea can be used.

More specifically, sight line detection is performed based on pupil center corneal reflection. The sight line vector representing the direction (rotation angle) of the eyeball is calculated based on the image of the pupil and the Purkinje image included in the captured image of the eyeball, using pupil center corneal reflection, thus detecting the user's line of sight.

In the present disclosure, the display device may include an imaging device having a light receiving element, and the image displayed on the display device may be controlled based on the user's line-of-sight information from the imaging device.

Specifically, the display device determines a first view field area at which the user gazes and a second view field area other than the first view field area based on the line-of-sight information. The first view field area and the second view field area may be determined by the controller of the display device, or the display device may receive those determined by an external controller. In the display region of the display device, the display resolution of the first view field area may be controlled to be higher than that of the second view field area. In other words, the resolution of the second view field area may be lower than that of the first view field area.

Also, the display region includes a first display area and a second display area different from the first display area, and the area with higher priority is determined from the first and second display areas based on the line-of-sight information. The first view field area and the second view field area may be determined by the controller of the display device, or the display device may receive those determined by an external controller. The resolution of the area taking priority may be controlled to be higher than that of the other area. In other words, the resolution may be lowered for the area with relatively low priority.

The first view field area or the area with higher priority may be determined using AI. The AI may be a model configured to estimate the angle of the line of sight from the image of the eyeball and the distance to an object beyond the line of sight, using as teacher data the image of the eyeball and the direction of the actual eyeball look. The AI program may be contained in the display device, the imaging device, or an external device. When contained in an external device, transmission to the display device is conducted through communication.

For display control based on visual detection, smart glasses further including an imaging device that captures external images are preferably used. The smart glasses can display the captured external information in real time.

As described above, the devices including the organic light-emitting element disclosed herein can display high-quality images stably in long-term display.

### Features Included

The present disclosure of the present disclosure includes the following.

### Feature 1

A metal complex represented by the following general formulas (1):

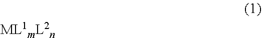

wherein in the above general formula (1), M represents Ir or Rh, and L¹ and L² represent ligands different from each other,

m represents an integer of 2 or 3, n represents an integer of 0 or 1, and m+n=3 holds true, and

ML¹ is represented by the following general formula (2), and ML² is represented by any of the following general formulas (3) to (5):

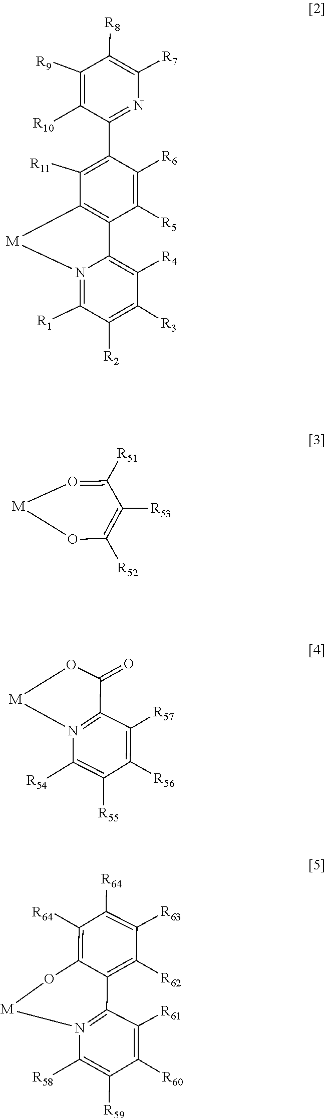

wherein in the above general formula (2), R₁ to R₁₁ are each independently selected from the group consisting of a hydrogen atom, a fluorine atom, a substituted or unsubstituted aryl group, a linear, branched, or cyclic alkyl group, and a triphenylsilyl group, and the hydrogen atoms of the alkyl and triphenylsilyl groups are optionally be substituted with an alkyl group or a fluorine atom, and

wherein in the above general formulas (3) to (5), R₅₁ to R₆₅ are each independently selected from the group consisting of a hydrogen atom, a deuterium atom, a halogen atom, a substituted or unsubstituted alkyl group, a substituted or unsubstituted alkoxy group, a substituted or unsubstituted aralkyl group, a substituted or unsubstituted amino group, a substituted or unsubstituted aryl group, and a substituted or unsubstituted heterocyclic group.

### Feature 2

The metal complex according to Feature 1, wherein the metal M in the above general formula (1) is Ir.

### Feature 3

The metal complex according to Feature 2, wherein m=3 and n=0 hold true in the above general formula (1).

### Feature 4

An organic light-emitting element including a first electrode, a second electrode, and an organic compound layer disposed between the first electrode and the second electrode, the organic compound layer including at least a light-emitting layer, wherein the light-emitting layer contains the metal complex according to any one of Features 1 to 3 as a light-emitting dopant.

### Feature 5

A display device including a plurality of pixels, wherein at least one of the pixels includes the organic light-emitting element according to Feature 4, and a transistor connected to the organic light-emitting element.

### Feature 6

An imaging device including an optical section including a plurality of lenses, an imaging element operable to receive light that has passed through the optical section, and a display section on which an image taken by the imaging element is displayed, wherein the display section includes the organic light-emitting element according to Feature 4.

### Feature 7

An electronic apparatus including a display section including the organic light-emitting element according to Feature 4, a housing provided with the display section, and a communication section that is provided at the housing and is operable to communicate with the outside.

### Feature 8

A lighting device including a light source including the organic light-emitting element according to Feature 4, and a light diffusing section or an optical filter that transmits light emitted from the light source.

### Feature 9

A movable apparatus including a lighting fixture including the organic light-emitting element according to Feature 4, and an apparatus body provided with the lighting fixture.

### EXAMPLES

The present disclosure will now be further described in detail with reference to Examples, but the disclosure is not limited to the following Example.

### Example 1

Example Compound 1 was synthesized according to the following process.

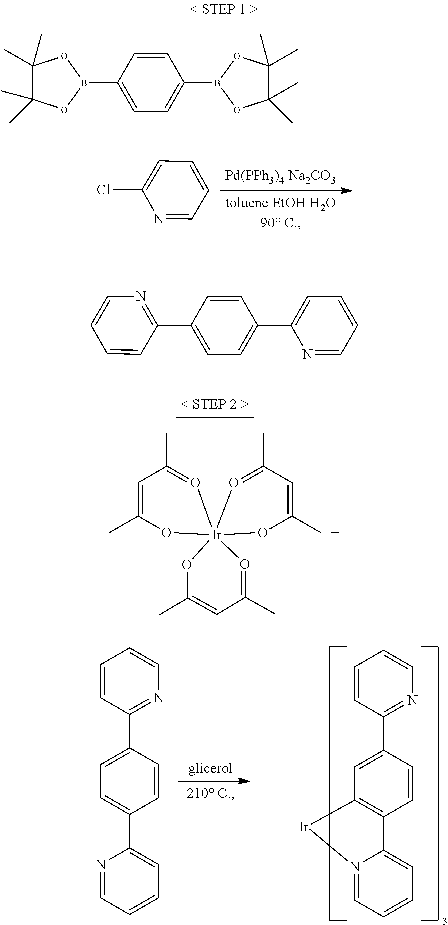

### Example Compound 1

### STEP 1: Synthesis of Ligand

Into a mixed solvent (15 mL of toluene, 10 mL of ethanol, and 10 mL of water) were added 3 mmol of 1,4-benzenediboronic acid bis(pinacol) ester, 9 mmol of 2-chloropyridine, 0.03 mmol of tetrakis(triphenylphosphine)palladium(0), and 12 mmol of sodium carbonate. The mixture was heated at 90° C. for 5 hours, and the reaction liquid was placed in a separating funnel. Using ethyl acetate and water, the organic layer (ethyl acetate) was extracted. The extract was filtered through Celite, dried with magnesium sulfate, and then concentrated in an evaporator. The resulting substance was purified through a silica gel column using ethyl acetate as the eluent to yield a ligand, 1,4-di(pyridin-2-yl)benzene.

The synthetic yield was 90%. Identification by gas chromatography-mass spectroscopy (GSMS) showed m/z=232.1.

### STEP 2: Synthesis of Ir Complex

In 100 mL three-neck flask, 0.25 mmol of iridium (III) acetylacetonate (Ir(acac)₃), 1 mmol of 1,4-di(pyridin-2-yl)benzene synthesized in the above STEP 1, and 10 mL of glycerol were placed and then heated and stirred at 210° C. for 5 hours under a nitrogen stream. The dark yellow sediment was placed in a separating funnel, and dichloromethane and water were added for extraction into the dichloromethane solution layer. The dichloromethane solution was washed with water three times to remove glycerol and dried with magnesium sulfate. Then, the dichloromethane solution was filtered through Celite. The resulting dichloromethane solution was concentrated in an evaporator. Then, the concentrate was purified by silica gel column chromatography using a solution of dichloromethane:heptane=9:1 as the eluent. Thus, Example Compound 1 was obtained with a purity of 99% and a yield of 40%.

### Analysis Data of Example Compound 1

The liquid chromatography-mass spectrometry (LC-MS) showed m/z=886.2, confirming that the target substance was obtained. The purity was determined by HPLC.

For X-ray crystallographic analysis, the product was left for one week for crystal growth using dichloromethane as a good solvent and methanol as a poor solvent. Substantially cube-shaped crystals with 0.5 mm sides were obtained, and these crystals were subjected to X-ray crystallographic analysis. FIG. 7 depicts a molecular structure image obtained by X-ray crystallographic analysis.

### Example 2

Example Compound 2 was synthesized according to the following process.

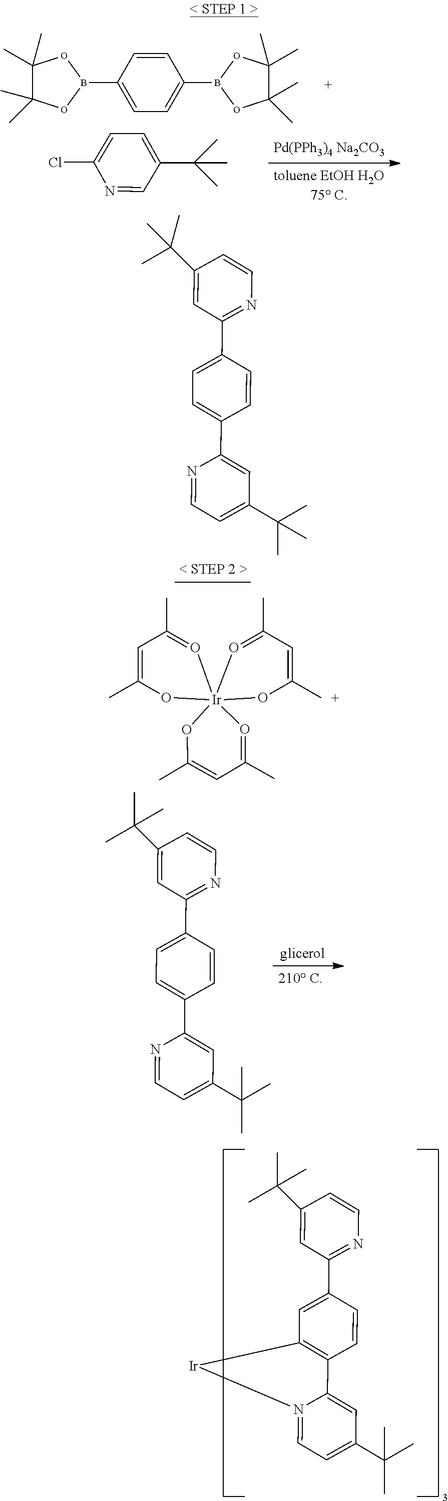

### Example Compound 2

### STEP 1: Synthesis of Ligand

Into a mixed solvent (15 mL of toluene, 10 mL of ethanol, and 10 mL of water) were added 5 mmol of 1,4-benzenediboronic acid bis(pinacol) ester, 15 mmol of 4-tert-butyl-2-chloropyridine, 0.05 mmol of tetrakis(triphenylphosphine)palladium(0), and 20 mmol of sodium carbonate. The mixture was heated at 75° C. for 8 hours, and the reaction liquid was placed in a separating funnel. Using ethyl acetate and water, the organic layer (ethyl acetate) was extracted. The extract was filtered through Celite, dried with magnesium sulfate, and then concentrated in an evaporator. The resulting substance was purified through a silica gel column using ethyl acetate as the eluent to yield a ligand, 1,4-di(4-tert-butylpyridin-2-yl)benzene. The synthetic yield was 70%. Identification by GSMS showed m/z=344.2.

### STEP 2: Synthesis of Ir Complex

In 100 mL three-neck flask, 0.25 mmol of Ir(acac)₃, 1 mmol of 1,4-di(4-tert-butylpyridin-2-yl)benzene synthesized in the above STEP 1, and 10 mL of glycerol were placed and then heated and stirred at 210° C. for 5 hours under a nitrogen stream. The dark yellow sediment was placed in a separating funnel, and dichloromethane and water were added for extraction into the dichloromethane solution layer. The dichloromethane solution was washed with water three times to remove glycerol. After drying with magnesium sulfate, the dichloromethane solution was filtered through Celite. The resulting dichloromethane solution was concentrated in an evaporator. Then, the concentrate was purified by silica gel column chromatography using a solution of dichloromethane: methanol=9:1 as the eluent. Thus, Example Compound 2 was obtained with a purity of 98% and a yield of 35%.

### Analysis Data of Example Compound 2

LC-MS showed m/z=1223, confirming that the target substance was obtained. The purity was determined by high performance liquid chromatography (HPLC).

### Performance Evaluation

The half width and quantum yield were determined for Example Compounds 1 and 2, synthesized in the above-described Examples 1 and 2, and Comparative Compounds 1 and 5 presented in Table 1 above. The emission spectrum and its half width were determined with a spectrophotometer “F4500” manufactured by Hitachi. For the luminescence quantum yield, 1×10⁻⁵ M solution was measured at room temperature with an absolute quantum yield measuring apparatus manufactured by Hamamatsu Photonics. The results are presented in Table 2.

The half widths of Example Compounds 1 and 2, which are metal complexes according to the present disclosure, were 31 nm and 26 nm, respectively, and are lower than the half widths of Comparative Compounds 1 and 5, which were 59 nm and 70 nm, respectively. The luminescence quantum yields of the toluene solutions of Example Compounds 1 and 2 were as high as 60% and 68%, respectively. These results show that the metal complexes according to the present disclosure provide emission with a narrow half width in the spectrum, hence high color purity, and with a high luminescence quantum yield.

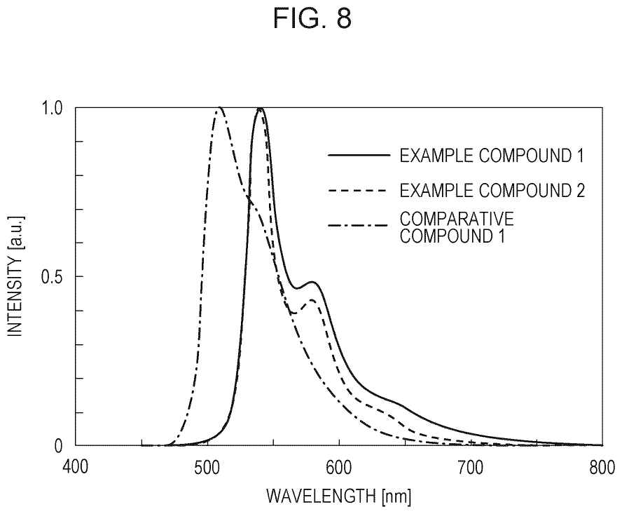

FIG. 8 is a representation of the normalized emission spectra of Example Compounds 1 and 2 and Comparative Compound 1. The emission spectra of Example Compounds 1 and 2 are narrower than the emission spectrum of Comparative Compound 1.

TABLE 2

| | Emission | Half | Luminescence |
|---|---|---|---|
| | peak (nm) | width (nm) | quantum yield |
| Example Compound 1 | 541 | 31 | 0.60 |
| Example Compound 2 | 538 | 26 | 0.68 |
| Comparative Compound 1 | 509 | 59 | 0.80 |
| Comparative Compound 5 | 545 | 70 | 0.48 |

### Example 3

Example Compound 3 was synthesized using the same process as in Example 2. The ligand used was 1,4-di(4-methylpyridin-2-yl)benzene. The synthetic yield in STEP 1 was 50%. Identification by GSMS showed m/z=260.1. The Synthesis of an Ir complex in STEP 2 produced Example Compound 3 with an HPLC purity of 98% and a yield of 35%. LC-MS analysis showed m/z=970.3, confirming that Example Compound 3 was obtained.

The results of emission performance evaluation are presented in Table 3. The half width in the emission spectrum was narrow.

TABLE 3

| | Emission | Half | Luminescence |
|---|---|---|---|
| | peak (nm) | width (nm) | quantum yield |
| Example Compound 3 | 540 | 32 | 0.76 |

### Example 4

In Example 4, Example Compound 33 was synthesized and its emission characteristics were evaluated.

The synthesis was performed in the following two steps. In STEP 1, first, iridium trichloride and a ligand, 1,4-di(4-methylpyridin-2-yl)benzene, were allowed to react at 100° C., and the resulting brown solid was filtered and washed with methanol to yield a dichloride species. The solid of the dichloride species was used in the reaction of STEP 2 without identification analysis. In STEP 2, the dichloride species and an auxiliary ligand, dipivaloylmethane, were allowed to react to yield Example Compound 33. LC-MS showed m/z=894.4, confirming that the target substance was obtained. The HPLC purity was 97%, and the synthetic yield in STEP 2 was 25%.

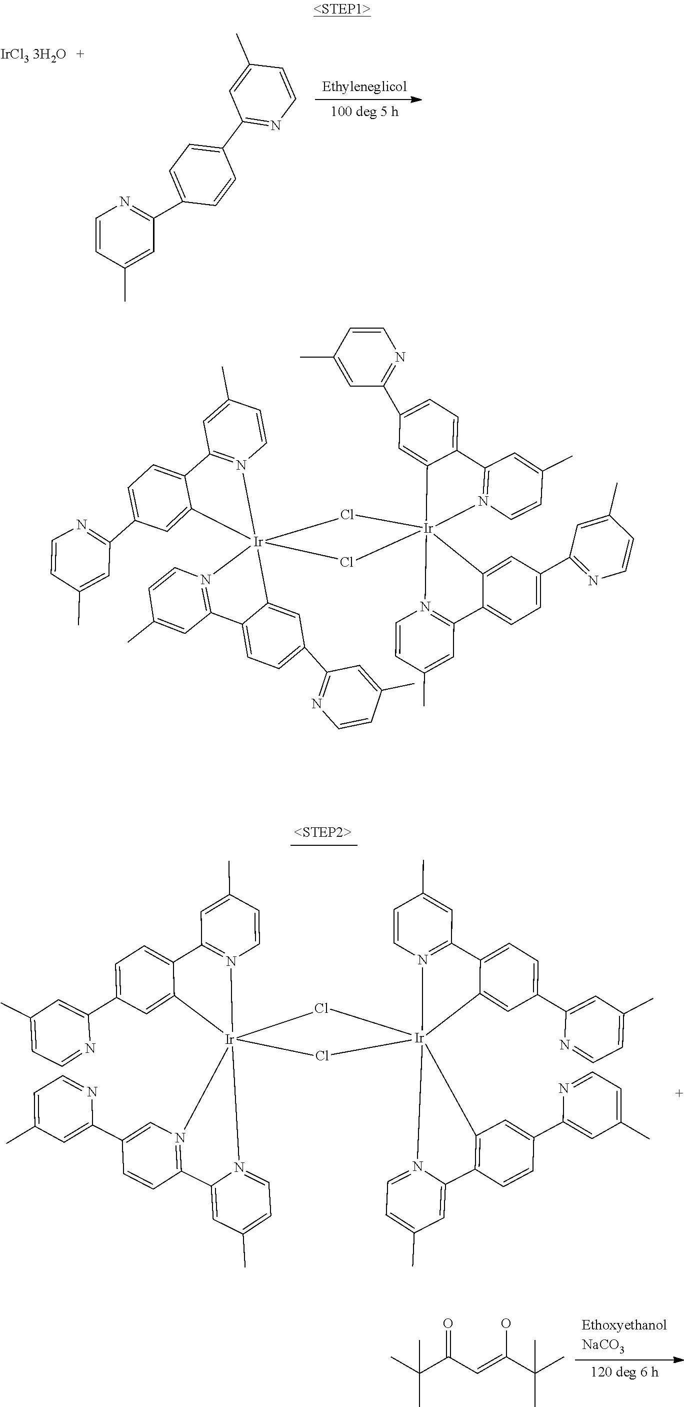

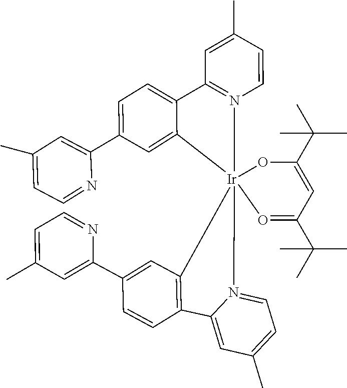

### Example Compound 33

The emission characteristics of Example Compound 33 were evaluated.

Example Compound 33 used in Example 4 has a basic skeletal structure different from the compounds of Examples 1 to 3. While the compounds of Examples 1 to 3 have tricoordinate structures in which three identical main ligands are coordinated, Example Compound 33 in Example 4 has a dpm-coordinated heteroleptic structure with two identical main ligands and one auxiliary ligand (dipivaloylmethane (dpm)). The performance of this Ir complex was evaluated with a focus on the “60% width”.

The 60% width refers to the spectral width at an emission intensity of 60% of the peak intensity in an emission spectrum. The 60% width is a spectral width of the more intense part of the emission spectrum and is considered to be an indicator for evaluating performance from the spectral shape.

A known Ir complex (Ir[ppy]₂dpm) presented below was synthesized as Comparative Compound 6. The results of performance evaluation are presented in Table 4. The value of Comparative Example 7 in Table 4 is that of metal complex A disclosed in the aforementioned NPL 2.

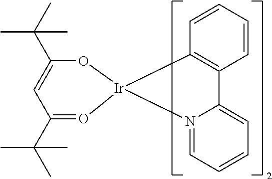

### Comparative Compound 6

TABLE 4

| | | 60% width |
|---|---|---|
| | Basic structure | (nm) |
| Example Compound 33 | dpm-Coordinated structure | 39 |
| Comparative Compound 6 | dpm-Coordinated structure | 46 |
| Comparative Compound 7 | dpm-Coordinated structure | 46 |

Comparison among the dpm-coordinated structures shows that the 60% width in the emission spectrum of Example Compound 33 is smaller than those of Comparative Compounds 6 and 7.

The present disclosure can provide a highly efficient, stable metal complex with a narrow half width and high color purity. Also, the use of the metal complex as a light-emitting dopant in an organic light-emitting element can provide a highly efficient optical device with high color purity.

While the present disclosure has been described with reference to exemplary disclosures, it is to be understood that the present disclosure is not limited to the disclosed exemplary disclosures. The scope of the following claims is to be accorded the broadest interpretation so as to encompass all such modifications and equivalent structures and functions.

1. A metal complex represented by the following general formulas (1): 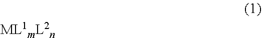
wherein in the above general formula (1), M represents Ir or Rh, and L¹ and L² represent ligands different from each other,
m represents an integer of 2 or 3, n represents an integer of 0 or 1, and m+n equals 3, and
ML¹ is represented by the following general formula (2), and ML² is represented by any of the following general formulas (3) to (5): 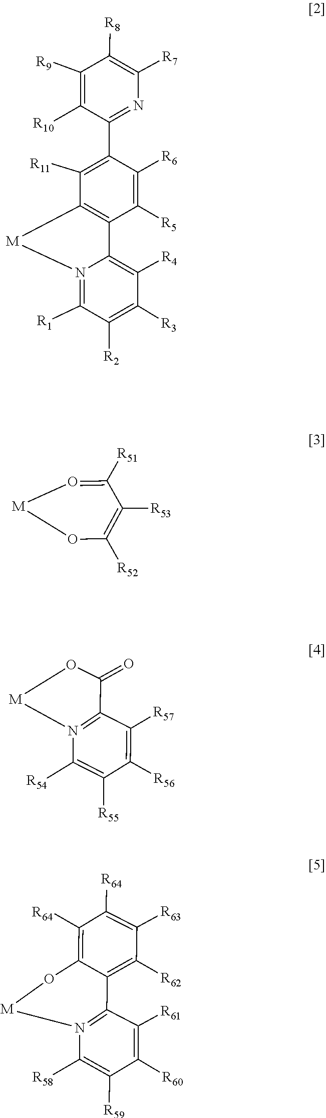
wherein in the above general formula (2), R₁ to R₁₁ are each independently selected from the group consisting of a hydrogen atom, a fluorine atom, a substituted or unsubstituted aryl group, a linear, branched, or cyclic alkyl group, and a triphenylsilyl group, and the hydrogen atoms of the alkyl and triphenylsilyl groups are optionally substituted with an alkyl group or a fluorine atom, and
wherein in the above general formulas (3) to (5), R₅₁ to R₆₅ are each independently selected from the group consisting of a hydrogen atom, a deuterium atom, a halogen atom, a substituted or unsubstituted alkyl group, a substituted or unsubstituted alkoxy group, a substituted or unsubstituted aralkyl group, a substituted or unsubstituted amino group, a substituted or unsubstituted aryl group, and a substituted or unsubstituted heterocyclic group.

2. The metal complex according to claim 1, wherein the metal M in the above general formula (1) is Ir.

3. The metal complex according to claim 2, wherein m equals 3 and n equals 0 in the above general formula (1).

4. The metal complex according to claim 1, wherein R₁ to R₁₁ are each independently selected from the group consisting of a hydrogen atom, a fluorine atom, a linear, branched, or cyclic C₁-C₆ alkyl group, and a triphenylsilyl group, and each hydrogen atoms of the alkyl group is optionally substituted with a fluorine atom.

5. The metal complex according to claim 1, wherein n is 1 and R₅₁ to R₆₅ are each independently selected from the group consisting of a hydrogen atom, a deuterium atom, a halogen atom, a substituted or unsubstituted C₁-C₆ alkyl group, a substituted or unsubstituted C₁-C₄ alkoxy group, a substituted or unsubstituted C₁-C₄ aralkyl group, a substituted or unsubstituted amino group, a substituted or unsubstituted C₅-C₇ aryl group, and a substituted or unsubstituted heterocyclic group having 2-5 carbon atoms and 1-3 nitrogen atoms.

6. An organic light-emitting element comprising: a first electrode; a second electrode; and an organic compound layer disposed between the first electrode and the second electrode, the organic compound layer including at least a light-emitting layer,
wherein the light-emitting layer contains the metal complex according to claim 1 as a light-emitting dopant.

7. A display device comprising: a plurality of pixels, wherein at least one of the pixels includes the organic light-emitting element according to claim 6, and a transistor connected to the organic light-emitting element.

8. An imaging device comprising: an optical section including a plurality of lenses; an imaging element operable to receive light that has passed through the optical section; and a display section on which an image taken by the imaging element is displayed,
wherein the display section includes the organic light-emitting element according to claim 6.

9. An electronic apparatus comprising: a display section including the organic light-emitting element according to claim 6; a housing provided with the display section; and a communication section provided at the housing, the communication section being operable to communicate with the outside.

10. A lighting device comprising: a light source including the organic light-emitting element according to claim 6; and a light diffusing section or an optical filter that transmits light emitted from the light source.

11. A movable apparatus comprising: a lighting fixture including the organic light-emitting element according to claim 6; and an apparatus body provided with the lighting fixture.
